(19) United States
(12) Patent Application Publication
(10) Pub. No.: US 2024/0186981 A1
(43) Pub. Date: Jun. 6, 2024

(54) MEMS and NEMS Resonators with Acoustic Metamaterial Lateral Anchors for Improved Performance and Linearity

(71) Applicant: Northeastern University, Boston, MA (US)

(72) Inventors: Cristian CASSELLA, Boston, MA (US); Xuanyi ZHAO, Brookline, MA (US); Onurcan KAYA, Boston, MA (US)

(21) Appl. No.: 18/218,797

(22) Filed: Jul. 6, 2023

Related U.S. Application Data
(60) Provisional application No. 63/358,822, filed on Jul. 6, 2022.
(60) Provisional application No. 63/438,836, filed on Jan. 13, 2023.

(51) Int. Cl. H03H 9/145; H03H 3/08; H03H 9/02; H03H 9/25

(52) U.S. Cl. CPC H03H 9/145; H03H 3/08; H03H 9/02543; H03H 9/25

(57) ABSTRACT

Provided herein are acoustic material (AM) CMRs having an active region including a conductive plate suspended over a cavity in a substrate and anchored to the substrate by two y-anchors, a piezoelectric layer disposed on the conductive plate, and an interdigitated metal structure (IDT) to cause transduction for excitement of a longitudinal mode of vibration of the AM CMR; and a pair of AM reflectors (AMRs) forming lateral anchors anchored to the substrate and attached to opposite sides of the conductive plate along the direction of vibration of the AM CMR, the AMRs each including a conductive anchor plate suspended over the cavity in the substrate, and a piezoelectric layer disposed on the conductive plate, and a parallel array of rods disposed on the piezoelectric layer, wherein the AMRs are configured to generate an acoustic stopband for inhibiting lateral leakage of the excited longitudinal mode of vibration.

### CROSS REFERENCE TO RELATED APPLICATIONS

This application claims benefit under 35 U.S.C. § 119(e) of U.S. Provisional Application No. 63/438,836, filed on 13 Jan. 2023, entitled “MEMS and NEMS Resonators with Acoustic Metamaterial Lateral Anchors for Improved Performance and Linearity” and U.S. Provisional Application No. 63/358,822, filed on 6 Jul. 2022, entitled “MEMS and NEMS Resonators with Acoustic Metamaterial Lateral Anchors for Improved Performance and Linearity,” the entirety of which is incorporated by reference herein.

### STATEMENT REGARDING FEDERALLY SPONSORED RESEARCH OR DEVELOPMENT

This invention was made with government support under Grant Number 2034948 awarded by the National Science Foundation, and Grant Number FA8650-21-1-7012 awarded by DARPA. The government has certain rights in the invention.

### BACKGROUND

The recent development of CMOS-compatible circulators has provided the fundamental means to build mobile communication systems for military and commercial applications relying on full-duplex radios (FDRs) to maximize the achievable spectral efficiency. Yet, due to the limited isolation that such circulators achieve, the use of FDRs in uncontrolled electromagnetic environments is only possible when electronically programmable self-interference (SI) cancellation networks, including a network of delay lines, are used in order to suppress the performance degradations due to leakage of the transmitted power into the receiver chain. In the last decades, several ADLs based on surface acoustic waves (SAW) or Lamb wave (LW) modes have been demonstrated. However, no ADL has shown the ability to achieve a large enough fractional bandwidth and a low enough insertion-loss (IL) to be used in the SI-cancellation networks of wideband FDRs, while preserving a CMOS-compatibility to favor their massive-scale production.

In the last decades, Aluminum Nitride (AlN) acoustic resonators have been developed and used for a broad range of applications, including frequency generation, timing, filtering, sensing, self-interference cancellation, and more. In particular, AlN Contour Mode Resonators (CMRs) have shown superior lithographic frequency tunability in a CMOS-compatible fabrication process, allowing to monolithically integrate multiple resonators with different resonance frequencies (fᵣₑₛ). CMRs are formed by a piezoelectric film sandwiched between two metal layers. Each CMR's suspended plate is generally connected to the substrate through two anchors placed along the in-plane direction (e.g., the y-direction) that is orthogonal to the main vibrational direction (e.g., the x-direction). Such anchors, referred to as y-anchors, generally present a narrow width (even lower than half wavelength, /2) to minimize the amount of acoustic energy leaking into the substrate. The mitigation of such energy leakage is key to prevent any reduction of the resonator's quality factor ( [symbol] ₛ). However, due to the requirement of narrow y-anchors to maximize [symbol] ₛ, the power handling of CMRs becomes primarily limited by thermally induced Duffing nonlinearity. Moreover, the use of thin-film AlN with relatively low thermal conductivity exacerbates this nonlinear phenomenon. Consequently, a trade-off exists, for CMRs, between power handling and maximum attainable [symbol] ₛ (and FoM=kₜ². [symbol] ₛ, being kₜ², the electromechanical coupling coefficient).

In recent years, the use of Scandium-doped Aluminum Nitride (AlScN) in microacoustic piezoelectric resonators has been largely investigated to boost the kₜ² of the AlN counterparts. Such a large interest is justified by the superior piezoelectric strength of AlScN in comparison to AlN. Yet, AlScN presents a thermal conductivity that is up to two orders of magnitude lower than AlN. As a result, all the existing AlScN resonators, including AlScN CMRs, are much more susceptible to Duffing nonlinearity than the AlN counterparts, inherently exhibiting lower power handling. This represents a huge limitation when using AlScN CMRs in filters, since it causes distortion and loss of information, and in oscillators, since it directly impacts frequency stability.

### SUMMARY

The present technology provides MEMS and NEMS resonators with acoustic metamaterial (AM)-based lateral anchors for improved performance and linearity. Such technology provides CMR designs capable of using AlScN or other piezoelectric materials having higher electromechanical coupling coefficients (kt²) than AlN by providing improved thermal dissipations for AlScN resonators without compromising their achievable [symbol] ₛ. In particular, CMRs are provided herein having a pair of AM-based lateral anchors attached along each of two lateral edges thereof in the form of compact frequency-selective reflective anchors, hereinafter referred to as acoustic metamaterials-based reflectors (AMRs). Using such AMRs along the lateral edges of an AlScN CMR, in combination with conventional narrow y-anchors, confines the acoustic energy within the resonator's active region while ensuring a much larger anchoring perimeter than conventional CMR designs. As a result, AMRs provide a substantial release path for the heat generated in the resonator's active region, mitigating the thermal nonlinearities with respect to conventional, laterally etched AlScN CMRs.

In one aspect, an acoustic material contour-mode resonator (AM CMR) is provided. The AM CMR includes an active region. The active region includes a conductive plate suspended over a cavity in a substrate, wherein the conductive plate is anchored to the substrate outside the cavity by two anchor structures at opposite sides of the conductive plate orthogonal to a direction of vibration of the AM CMR (y-anchors). The active region also includes a piezoelectric layer comprising a sheet disposed on the conductive plate, wherein the sheet comprises a piezoelectric material. The active region also includes an interdigitated metal structure (IDT) configured to generate an electric field in the piezoelectric layer to cause transduction for excitement of a longitudinal mode of vibration of the AM CMR. The AM CMR also includes a pair of acoustic metamaterial reflectors (AMRs) forming lateral anchors anchored to the substrate and attached to opposite sides of the conductive plate along the direction of vibration of the AM CMR. The AMRs each include a conductive anchor plate suspended over the cavity in the substrate. The AMRs each also include a piezoelectric layer comprising a sheet disposed on the conductive plate, wherein the sheet comprises a piezoelectric material, and a parallel array of rods disposed on the sheet, wherein the sheet comprises a piezoelectric material. The AMRs are also configured to generate an acoustic stopband for inhibiting lateral leakage of the excited longitudinal mode of vibration of the AM CMR.

In some embodiments, the IDT includes a plurality of electrodes configured to generate the electric field in the piezoelectric layer. In some embodiments, the piezoelectric material is a highly doped aluminum nitride material. In some embodiments, the piezoelectric material is Al_{0.72}Sc_{0.28}N. In some embodiments, the parallel array of rods includes one or more rods. In some embodiments, the parallel array of rods includes between one to 20 rods. In some embodiments, the parallel array of rods includes seven rods. In some embodiments, the rods comprise one or more of a dielectric, metallic, or piezoelectric material.

In some embodiments, a minimum length Lᵣ^{min} of each AMR lateral anchor for achieving [symbol] ₛ≥0.9 is less than a Lᵣ^{min} of a metal reflector (MR) attached to an MR CMR having a same active region as the AM CMR. In some embodiments, a minimum length Lᵣ^{min} of each AMR lateral anchor for achieving [symbol] ₛ/ [symbol] ₘₐₓ≥0.9 is less than 100 μm. In some embodiments, a minimum length Lᵣ^{min} of each AMR lateral anchor for achieving [symbol] ₛ≥0.9 is less than 70 μm. In some embodiments, the piezoelectric layer comprises a corrugated structure, wherein the corrugated structure is characterized by a repeating unit-cell structure defined by a cross-section of the piezoelectric material sheet and the rods. In some embodiments, each of the rods has a thickness (Tᵣ) of 350 nm. In some embodiments, each of the rods has a width (Wᵣ) of 4 μM.

In another aspect, a method of fabricating an acoustic material contour-mode resonator (AM CMR) is provided. The method includes depositing a conductive layer onto a substrate. The method also includes depositing a piezoelectric layer onto the conductive layer. The method also includes depositing an interdigitated metal structure (IDT) onto an active region portion of the piezoelectric layer. The method also includes forming, in two separate acoustic metamaterial reflector (AMR) portions of the piezoelectric layer, two corrugated structures each comprising an array of parallel rods. The method also includes etching a release pit beneath the conductive layer, thereby forming the AM CMR.

In some embodiments, the step of forming the array of parallel rods in the piezoelectric layer of each of the two corrugated structures further comprises etching troughs into each of the two separate AMR portions of the piezoelectric layer. In some embodiments, the step of forming the array of parallel rods in the piezoelectric layer of each of the two corrugated structures further comprises depositing a set of dielectric or conducting rods onto the piezoelectric layer in each of the two separate AMR portions of the piezoelectric layer. In some embodiments, the AMR portions of the piezoelectric layer are positioned on opposite sides of and attached to the active region portion. In some embodiments, after the step of etching the release pit, the AMR portions of the piezoelectric layer remain anchored to the substrate. In some embodiments, the method is CMOS compatible.

Additional features and aspects of the technology include the following:

1. An acoustic material contour-mode resonator (AM CMR) comprising:
an active region including:
   a conductive plate suspended over a cavity in a substrate, wherein the conductive plate is anchored to the substrate outside the cavity by two anchor structures at opposite sides of the conductive plate orthogonal to a direction of vibration of the AM CMR (y-anchors),
   a piezoelectric layer comprising a sheet disposed on the conductive plate, wherein the sheet comprises a piezoelectric material, and
   an interdigitated metal structure (IDT) configured to generate an electric field in the piezoelectric layer to cause transduction for excitement of a longitudinal mode of vibration of the AM CMR; and
a pair of acoustic metamaterial reflectors (AMRs) forming lateral anchors anchored to the substrate and attached to opposite sides of the conductive plate along the direction of vibration of the AM CMR, the AMRs each including:
   a conductive anchor plate suspended over the cavity in the substrate, and
   a piezoelectric layer comprising a sheet disposed on the conductive plate, wherein the sheet comprises a piezoelectric material, and a parallel array of rods disposed on the sheet, wherein the sheet comprises a piezoelectric material;
wherein the AMRs are configured to generate an acoustic stopband for inhibiting lateral leakage of the excited longitudinal mode of vibration of the AM CMR.
   2. The AM CMR of feature 1, wherein the IDT includes a plurality of electrodes configured to generate the electric field in the piezoelectric layer.
   3. The AM CMR of any of features 1-2, wherein the piezoelectric material is a highly doped aluminum nitride material.
   4. The AM CMR of feature 3, wherein the piezoelectric material is Al_{0.72}Sc_{0.28}N.
   5. The AM CMR of any of features 1-4, wherein the parallel array of rods includes one or more rods.
   6. The AM CMR of feature 5, wherein the parallel array of rods includes between one to 20 rods.
   7. The AM CMR of feature 6, wherein the parallel array of rods includes seven rods.
   8. The AM CMR of any of features 1-7, wherein the rods comprise one or more of a dielectric, metallic, or piezoelectric material.
   9. The AM CMR of any of features 1-8 wherein a minimum length Lᵣ^{min} of each AMR lateral anchor for achieving [symbol] ₛ≥0.9 is less than a Lᵣ^{min} of a metal reflector (MR) attached to an MR CMR having a same active region as the AM CMR.
   10. The AM CMR of feature 9, wherein a minimum length Lᵣ^{min} of each AMR lateral anchor for achieving [symbol] ₛ/ [symbol] ₘₐₓ≥0.9 is less than 100 μm.
   11. The AM CMR of feature 10, wherein a minimum length Lᵣ^{min} of each AMR lateral anchor for achieving [symbol] ₛ≥0.9 is less than 70 μm.
   12. The AM CMR of any of features 1-11, wherein the piezoelectric layer comprises a corrugated structure, wherein the corrugated structure is characterized by a repeating unit-cell structure defined by a cross-section of the piezoelectric material sheet and the rods.
   13. The AM CMR of any of features 1-12, wherein each of the rods has a thickness (Tᵣ) of 350 nm.
   14. The AM CMR of any of features 1-13, wherein each of the rods has a width (Wᵣ) of 4 μm.
   15. A method of fabricating an acoustic material contour-mode resonator (AM CMR) comprising the steps of:
depositing a conductive layer onto a substrate;
depositing a piezoelectric layer onto the conductive layer;
depositing an interdigitated metal structure (IDT) onto an active region portion of the piezoelectric layer;
forming, in two separate acoustic metamaterial reflector (AMR) portions of the piezoelectric layer, two corrugated structures each comprising an array of parallel rods; and
etching a release pit beneath the conductive layer, thereby forming the AM CMR.
   16. The method of feature 15, wherein the step of forming the array of parallel rods in the piezoelectric layer of each of the two corrugated structures further comprises etching troughs into each of the two separate AMR portions of the piezoelectric layer.
   17. The method of any of features 15-16-, wherein the step of forming the array of parallel rods in the piezoelectric layer of each of the two corrugated structures further comprises depositing a set of dielectric or conducting rods onto the piezoelectric layer in each of the two separate AMR portions of the piezoelectric layer.
   18. The method of any of features 15-17, wherein the AMR portions of the piezoelectric layer are positioned on opposite sides of and attached to the active region portion.
   19. The method of any of features 15-18, wherein, after the step of etching the release pit, the AMR portions of the piezoelectric layer remain anchored to the substrate.
   20. The method of any of features 15-19, wherein the method is CMOS compatible.

### BRIEF DESCRIPTION OF THE DRAWINGS

FIG. 1A shows a schematic illustration of an embodiment of an acoustic delay line (ADL) according to the present technology. The ADL includes two wideband input/output terminals and a corrugated structure between them. The corrugated structure creates an acoustic metamaterial and forms passbands depending on the geometry of the unit cell.

FIG. 1B shows a corrugated structure of an ADL depicting an acoustic wave outside of its passband.

FIG. 1C shows a corrugated structure of an ADL depicting an acoustic wave inside of its passband.

FIGS. 2A and 2B show the simulated performance of a 2D rod array of an ADL. FIG. 2A indicates a fractional bandwidth of 11%, and FIG. 2B indicates an insertion loss of 0.86 dB. The inset of FIG. 2A represents propagation of an acoustic wave within the metamaterial.

FIGS. 3A-3C show scanning electron micrographs (SEM) of actual ADL devices. FIG. 3A shows a top view of a 3 array ADL, and FIG. 3B shows a close-up of a single element thereof. FIG. 3C shows a cross-sectional view of a unit cell during fabrication, with an oxide masking layer on top of a rod structure.

FIG. 4A shows the measured performance of an ADL having high fractional bandwidth of 7.5% and an insertion loss of 1.8 dB.

FIG. 4B shows, for the same device, a group delay from about 30 ns to 50 ns over the bandwidth.

FIG. 5 shows a schematic representation of an embodiment of a fabrication process for an ADL device according to the present technology.

FIGS. 6A and 6B show cross-sectional schematic views of the corrugated structure of an ADL with unit cell features labeled. FIG. 6C shows real and imaginary parts of the analytically calculated k_{eff} for an ADL of the present technology. FIG. 6D shows the analytically calculated trend of T vs. frequency for an ADL of the present technology.

FIG. 7A shows a SEM of a system comprising a three-element fabricated ADL and four simulated switchable matching networks (I-IV) at each of the input and output terminals. Each of the matching networks has a different passband (corresponding to matching networks I-IV). Depending on the selected matching networks, the single device can be re-programmed to operate within different frequency bands.

FIG. 7B shows both simulated (dashed lines) and measured (solid lines) responses of the ADL of FIG. 7A after matching to 50Ω within different passbands.

FIG. 7C shows close up views of data for the FEM-simulated (dashed lines) and measured (solid lines) insertion loss and group delay for each of the passbands shown in FIG. 7B.

FIG. 8A illustrates a SEM image of a conventional CMR design supported only by two narrow y-anchors (CMR^{CNV}).

FIG. 8B illustrates a schematic cross-sectional view of the CMR^{CNV}, including modeled total displacement at 480 MHz.

FIG. 9A illustrates a SEM image of a CMR design with un-etched lateral sides (CMR^{CTL}).

FIG. 9B illustrates a schematic cross-sectional view of the CMR^{CTL}, including modeled total displacement at 480 MHz.

FIG. 10 illustrates a comparison of the measured admittance response for CMR^{CNV} and CMR^{CTL}.

FIG. 11A illustrates an SEM image of a CMR design having a pair of AMRs attached along each of two lateral sides thereof (CMR^{AM}). The exemplary CMR^{AM} device shown includes two AMRs, each having seven unit-cells.

FIG. 11B illustrates a cross-sectional view of a CMR^{AM} of N unit-cells having a pair of AMRs attached along each of two lateral sides thereof.

FIG. 11C illustrates a cross-sectional view of a unit-cell of one of the AMRs of FIG. 11B. In the example embodiment shown, the unit cell includes an AlScN rod on top of a Pt/AlScN plate.

FIG. 12A illustrates admittance magnitude results from an FEM-analysis of a plurality of CMR^{CNV} having different interdigitated metal structure (IDT) pitch (Wₚ) values.

FIG. 12B illustrates at-resonance total displacement modeshape results from an FEM-analysis of a plurality of CMR^{AM} having different interdigitated metal structure (IDT) pitch (Wₚ) values.

FIG. 12C illustrates admittance magnitude results from an FEM-analysis of a plurality of CMR^{AM} having different interdigitated metal structure (IDT) pitch (Wₚ) values.

FIG. 12D illustrates at-resonance total displacement modeshape results from an FEM-analysis of a plurality of CMR^{AM} having different interdigitated metal structure (IDT) pitch (Wₚ) values.

FIG. 12E illustrates acoustic transmission (T) vs. frequency of the AMRs used by the CMR^{AM} analyzed in FIGS. 12C and 12D.

FIG. 12F illustrates total pressure distribution at two different frequencies, within or outside of the widest AMR bandgap (BG) of the AMRs used by the CMR^{AM} analyzed in FIGS. 12C and 12D.

FIG. 12G illustrates lateral wavevector (kₓ) for the contour-mode vs. frequency of the AMRs used by the CMR^{AM} analyzed in FIGS. 12C and 12D, showing the existence of two BGs.

FIG. 12H illustrates a schematic cross-sectional view of unit-cell and boundary conditions used to extract the lateral wavevector (kₓ) for the contour-mode vs. frequency of the AMRs used by the CMR^{AM} illustrated in FIG. 12G.

FIG. 13A illustrates a plot of FEM-extracted transmission of the AMRs used in FIGS. 12C and 12D vs. frequency for varying the thicknesses of the rods (Tᵣ)

FIG. 13B illustrates a plot of kₓ for the contour-mode vs. frequency of the AMRs used by the CMR^{AM} analyzed in FIG. 13A and for the same Tᵣ values used in FIG. 13A.

FIG. 14 illustrates a comparison between the trends of the kₓ of the contour-mode vs. frequency for AMRs, for metal reflectors (MRs) made of aluminum, and for MRs made of platinum.

FIG. 15A illustrates a 3D Schematic view of a CMR using MRs along its lateral sides.

FIG. 15B illustrates a 3D Schematic view of a CMR using AMRs along its lateral sides.

FIG. 15C illustrates a plot of simulated [symbol] ₛ vs. the lateral length (L r) of each adopted reflector for a CMR^{AM} using the unit-cell geometry described in FIGS. 15D, 15F, and 15H, a CMR using MRs made of platinum, and a CMR using MRs made of aluminum. The plotted [symbol] ₛ-values are normalized to an arbitrarily selected maximum value which was set to 10000 in the FEM simulation. The Lᵣ^{min} value for each of the investigated topologies is also listed in the inset.

FIG. 16 illustrates a 3D-FEM study for the extraction of Rₜₕ for CMR^{CNV}, CMR^{AM}_{Nu=7}, and for CMRs using aluminum and platinum MRs along their sides. For both the aluminum MRs and the platinum MRs, a length equal to the corresponding Lᵣ^{min} values FIGS. 18A and 18B was selected. The extraction of Rₜₕ for all these devices passed through the evaluation of the average temperature originated in their suspended portion when applying a 1 mW power in their active regions and after setting heatsinks at the outer edges of all the anchors. The extracted values of Rₜₕ are listed for all the considered cases.

FIG. 17 shows a schematic representation of an embodiment of a fabrication process for a CMR^{AM} device according to the present technology.

FIGS. 18A-18B illustrate a top-view SEM image and XRD 2-theta and Omega scans of an Al_{0.72}Sc_{0.28}N film used in fabrication according to FIG. 17, showing the AlScN film's low density of abnormally oriented grains (AOGs), as well as its good crystallinity resulting in a rocking curve with 1.9° Full-Width-Half-Maximum (FWHM).

FIG. 19A illustrates measured wide-span admittance response for the best performing CMR^{CNV} and CMR^{AM}_{Nu=7} tested as described herein.

FIG. 19B illustrates admittance magnitude (|Y|) for CMR^{CNV}, CMR^{CTL}, and CMR^{AM} [1,3,5,7] within a span ranging from 435 MHz to 535 MHz.

FIG. 19C illustrates measured trends of [symbol] ₛ and [symbol] ₚ vs. the number of adopted unit-cells for CMR^{AM} [1,3,5,7] and CMR^{CTL}. The [symbol] ₛ and [symbol] ₚ values exhibited by CMR^{CNV}, are also illustrated.

FIG. 20A illustrates measured admittance response and the fitted values of α_{A-f} of the best performing CMR^{CNV} device tested as described herein vs. input driving power.

FIG. 20B illustrates measured admittance response and the fitted values of α_{A-f} vs. input driving power for a CMR^{AM}_{Nu=7} device with the same at-resonance admittance magnitude as the CMR^{CNV} used in FIG. 22A.

### DETAILED DESCRIPTION

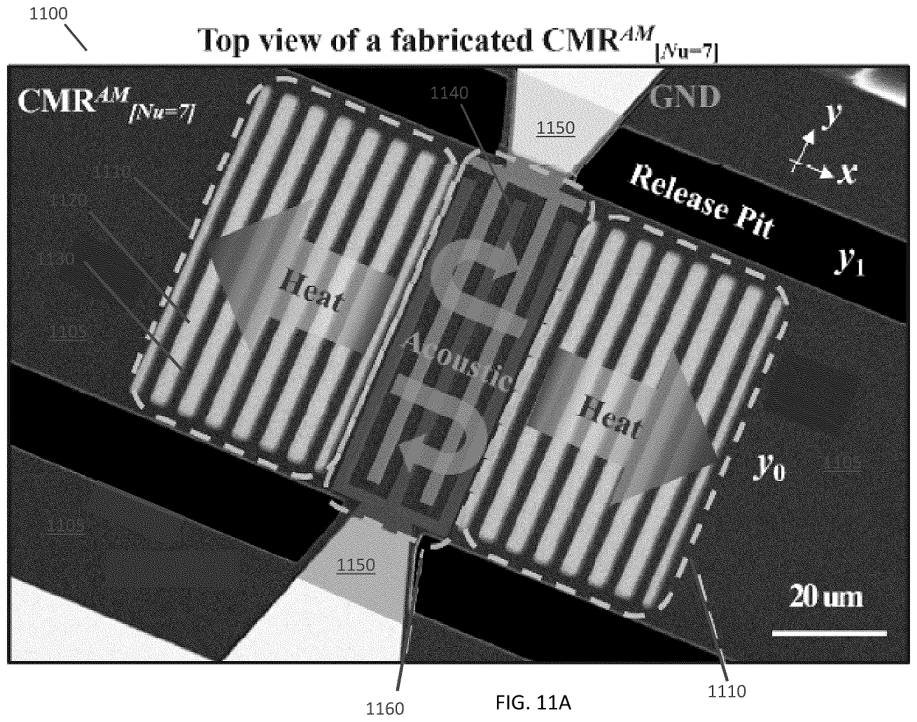

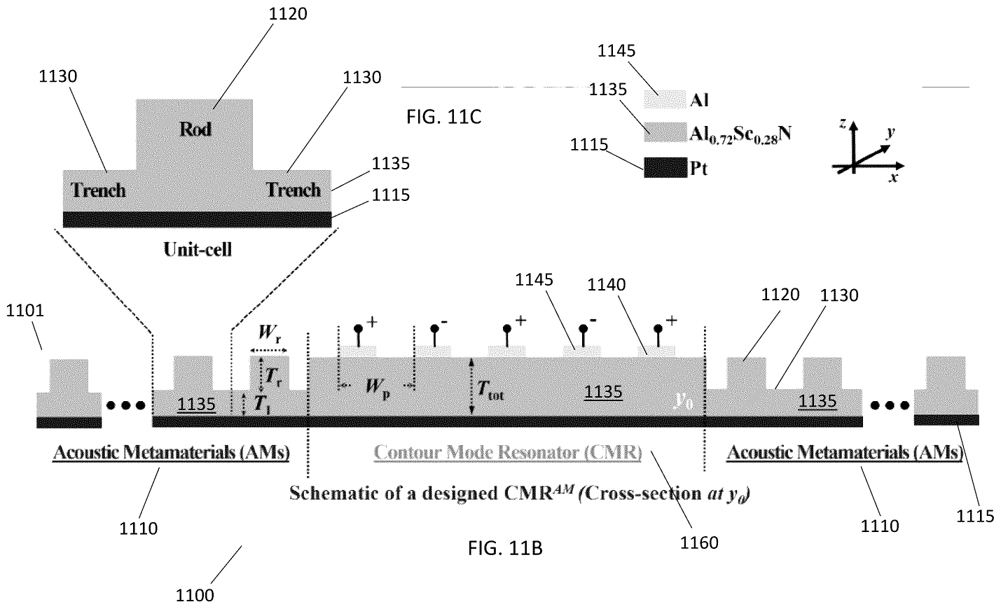

Provided herein are MEMS and NEMS resonators with acoustic metamaterial (AM) lateral anchors for improved performance and linearity. Such devices include contour mode resonators (CMRs) having a pair of AM-based lateral anchors attached along each of two lateral edges thereof in the form of compact frequency-selective reflective anchors, hereinafter referred to as acoustic metamaterials-based reflectors (AMRs). Such CMRs having a pair of AMRs attached along each of two lateral edges thereof in combination with conventional narrow y-anchors (hereinafter “CMR^{AM}”), confines the acoustic energy within the resonator's active region. In addition, such CMR^{AM}s provide a much larger anchoring perimeter than conventional CMR designs and, as such, the AMRs provide improved heat dissipation in the resonator's active region, mitigating the thermal nonlinearities with respect to conventional, laterally etched AlScN CMRs (CMR^{CNV}). For example, FIGS. 11A-11C illustrate an exemplary fabricated AL_{0.72}Sc_{0.28}N CMR^{AM} attached to a substrate via both y-anchors and AMRs.

### Acoustic Metamaterials

Acoustic metamaterials (AMs) can generally be formed by arrays of rods (e.g., locally resonant rods) constructed of one or more piezoelectric materials such as AlN, AlScN, or other high kₜ² piezoelectric materials. Such AMs present unique acoustic properties because they are designed to have specific dispersion characteristics that alternate acoustic passbands and stopbands within a desired range of frequencies. For instance, piezoelectric AMs-based devices embodying a forest of rods (e.g., resonant rods) can be designed to suppress any high order Lamb waves via a stopband, increasing the mechanical energy of two-dimensional modes of vibration piezoelectrically transduced in all the rods. These AMs devices constitute a new class of Bulk-Acoustic-Wave (BAW) resonators, namely the Two-Dimensional-Resonant-Rods (2DRRs). 2DRRs are characterized by a considerably larger kₜ² than other AlN or AlScN resonators operating within the same band. In a separate application, these same AMs can be used to form acoustic delay lines, offering wide fractional bandwidths and high group delays enabled by the slow-wave propagation characteristics of the AMs-based structure, as described below.

### Application of Acoustic Metamaterials to Acoustic Delay Lines

2DRR based acoustic delay lines (ADLs) for operation in the radio frequency (RF) range are described herein. Contrary to any other ADLs reported to date, which are based on the piezoelectric excitation of surface acoustic waves (SAW) or Lamb waves (LW), the ADLs described here rely on the lithographically defined artificial dispersive characteristics of acoustic metamaterials formed by forests of rods (e.g., locally resonant rods). Further improved characteristics can be obtained by using piezoelectric materials having high piezoelectric coefficients, such as highly doped aluminum scandium nitride (Al_{0.64}Sc_{0.36}N) films. The 2DRR-based ADLs described here can operate over the entire ultra-high frequency and super high frequency range, for example, at 133 MHz with a record-high fractional bandwidth of up to 15% (limited only by the bandwidth of the matching networks) and an insertion loss (IL) of less than 2 dB. These functional characteristics surpass the fundamental limits in bandwidth and IL of conventional SAW and LW counterparts.

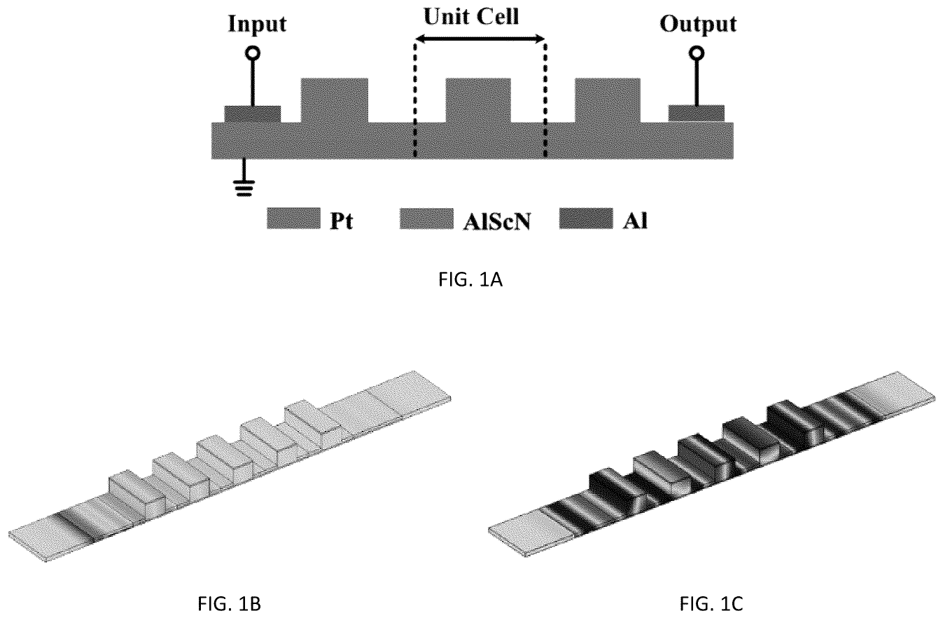

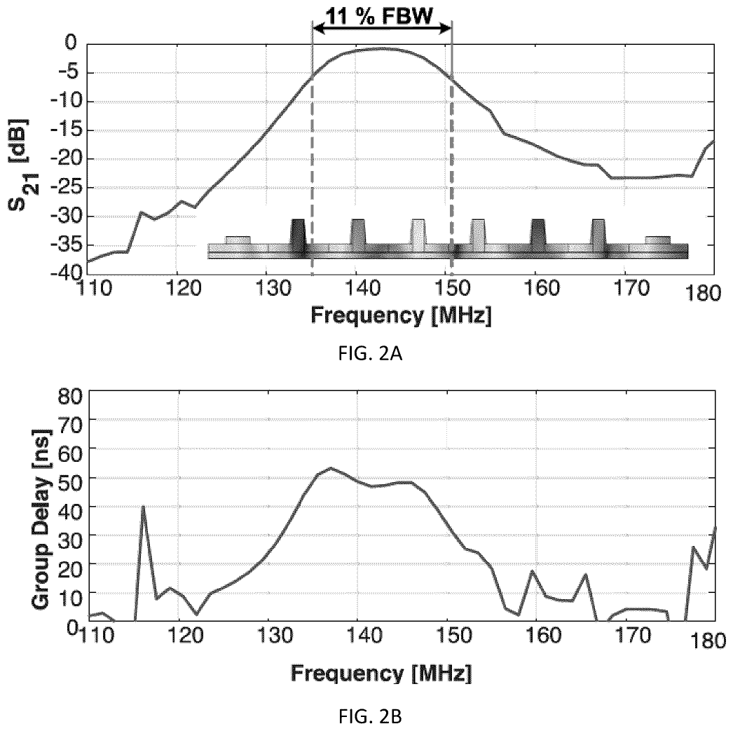

These ADL devices possess wideband input/output terminals separated by a corrugated structure forming an acoustic metamaterial (FIG. 1A). The corrugated structure, which is formed by a forest of Al_{0.64}Sc_{0.36}N rods, creates passbands (see FIGS. 1B, 1C) with bandwidths exceeding those achievable in conventional counterparts without requiring expensive materials, like LiNbO₃, which are not compatible with conventional CMOS processes. The unique performance features of the present 2DRR-based ADL were verified through Finite Element Methods (FEM, see FIGS. 2A, 2B).

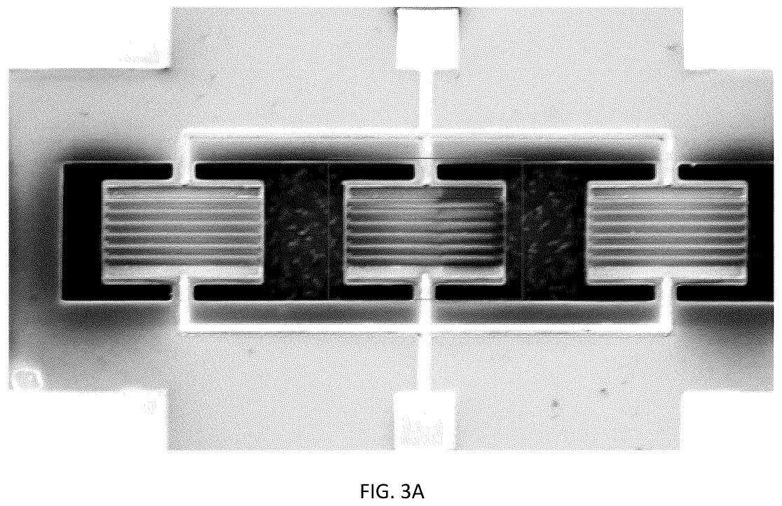

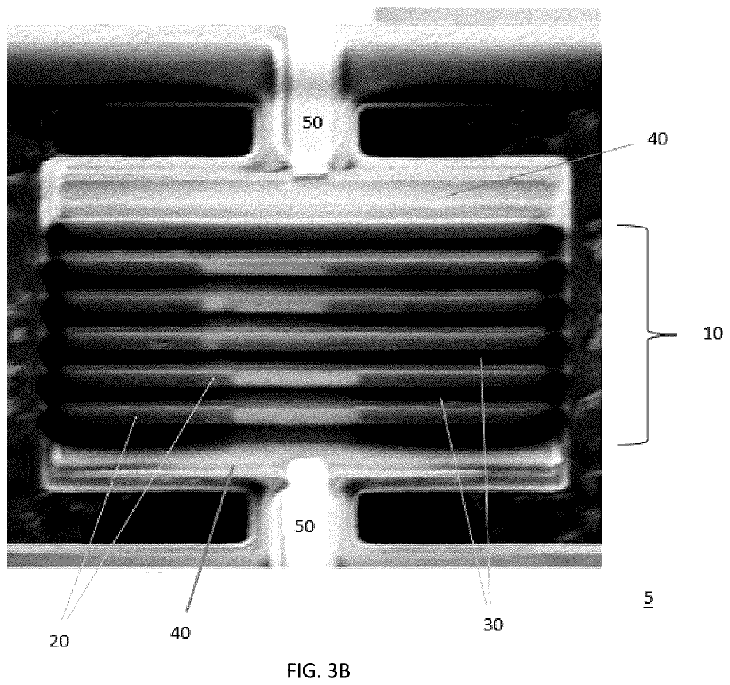

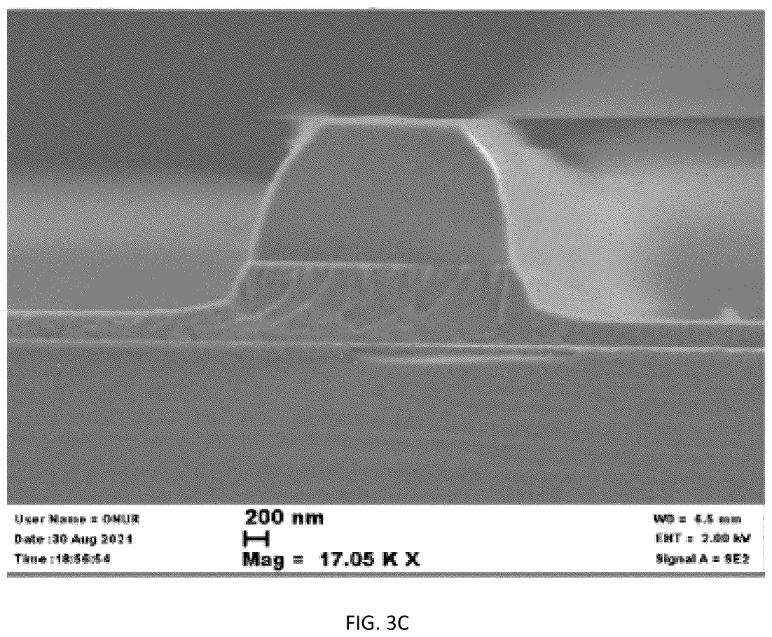

A scanning electron micrograph of the corrugated portion of an actual fabricated ADL device is shown in FIGS. 3A-3C. FIG. 3A shows a single device having three individual ADLs coupled in parallel to single input and output terminals. FIG. 3B shows a close-up view of one of the individual devices. FIG. 3C shows a cross-section of a rod and adjacent troughs, with an oxide mask from the fabrication process still present on top of the rod.

The individual array unit of FIG. 3B can include an ADL 5 having a 2D rod array 10 disposed between two AL electrodes 40, (input/output terminals) which are connected via conductive paths through anchor structures 50 to conductive pads on the adjacent chip (not shown). The electrodes can be any conductive metal, such as Pt, Al, Mo, Cr, Ti, W, or Cu. The anchor structures are made of a beam of AlScN sandwiched between two platinum layers. Rod array 10 contains a group of rods 20 in parallel arrangement and separated by troughs 30. In this embodiment, the rods and troughs are formed by partially etching a single layer of Al_{0.64}Sc_{0.36}N piezoelectric material.

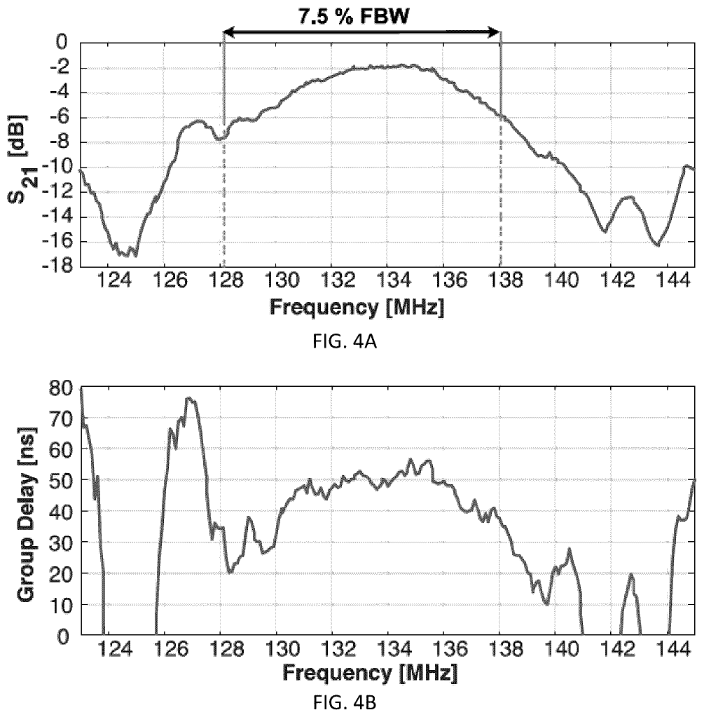

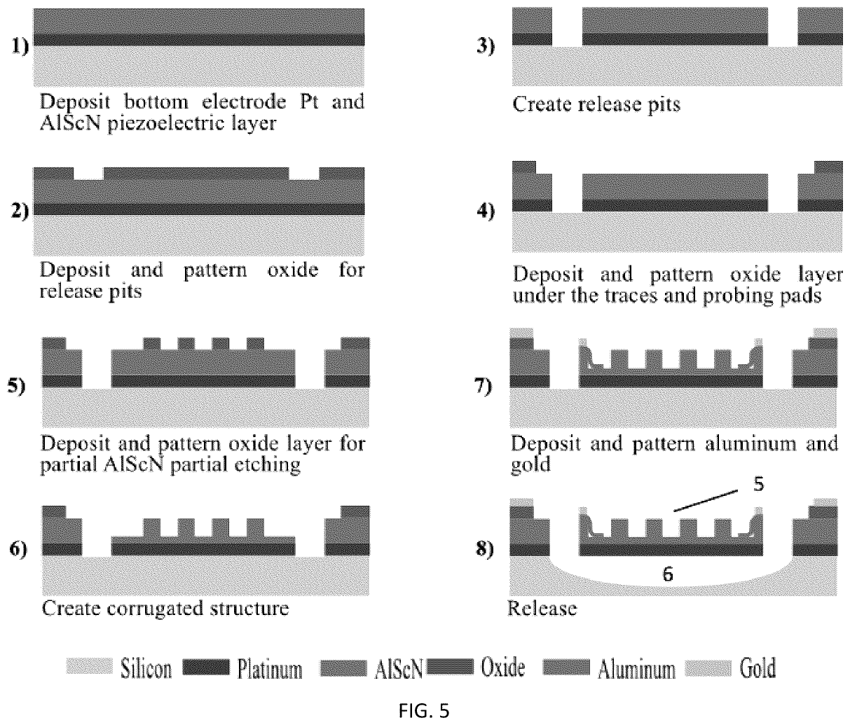

The performance of a fabricated ADL was characterized using a Network Analyzer, and the results are shown in FIGS. 4A and 4B. As evident, the constructed device exhibited record-high bandwidth and IL values of 7.5% and 1.8 dB when assuming conjugate matching as well as a group delay of nearly 50 ns. The delay is a function of the number of rods in the array and can be increased by increasing the size of the rod array.

An exemplary process used to fabricate the present ADL devices is shown in FIG. 5, together with information about its material stack. The process began with the deposition of a bottom unpatterned 100 nm thick (t_{Pt}=100 nm) platinum layer (conductive substrate), followed by the sputtering of a 500 nm-thick Al_{0.64}Sc_{0.36}N film onto the platinum layer. Secondly, the release holes for the structural release (i.e., to obtain a suspended ADL device attached to the chip via small anchor structures on opposite sides of the suspended device) were formed by etching the AlScN film with a SiO₂ hard mask. Following that, another silicon dioxide layer was deposited and patterned to be used under probing pads to reduce associated parasitic capacitance. Later, the corrugated structure was built by partial etching (removing 80% of the thickness) of the AlScN film through the adoption of a third SiO₂ mask. Then, the top 140 nm thick Al electrode was patterned, forming the input and output terminals, followed by the deposition of the 300 nm thick gold terminals on top of the Al terminals as well as on the probing pads positioned on the adjacent silicon chip. Finally, the device was released through a XeF₂ Si-etch, leaving it attached to the chip through two small anchor structures at opposite ends of the device. Each anchor includes a beam of the piezoelectric material sandwiched between platinum layers, the lower of which is grounded.

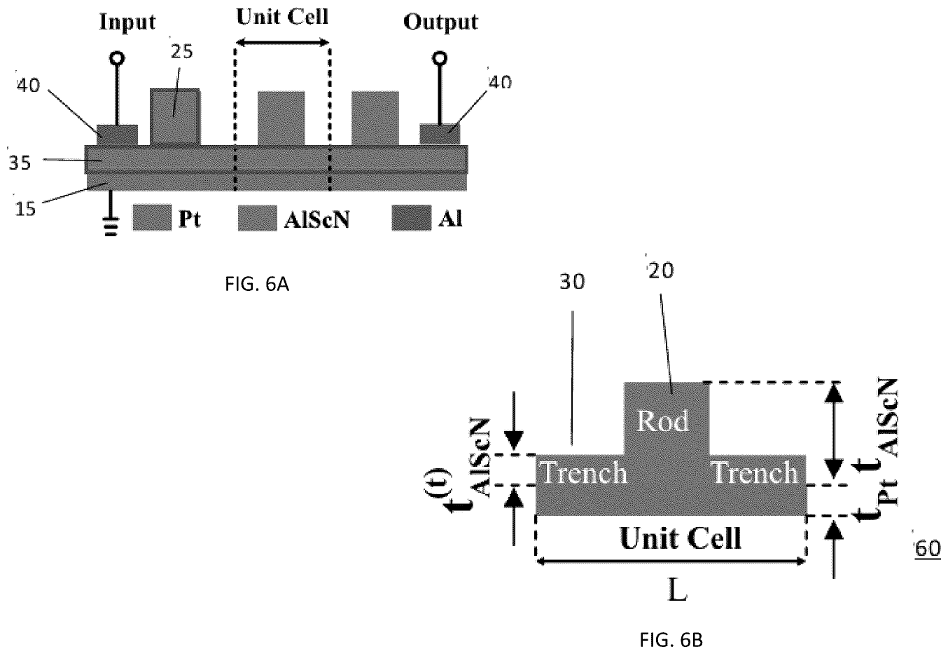

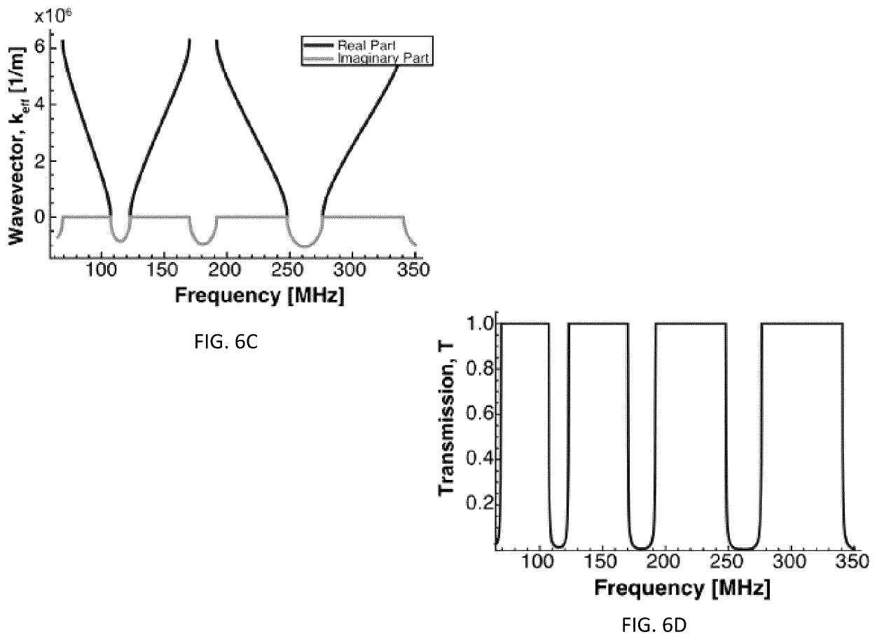

In the exemplified device, the corrugated structure included 8 rods containing scandium-doped aluminum nitride, connected by thin trenches of the same material. The propagation wavevectors depend on the dimensions and mechanical properties (determined by the selection of material) of the unit cell. FIGS. 6A and 6B depict the unit cell of the corrugated structure. In FIG. 6A can be seen conductive substrate layer 15, upon which is disposed sheet of piezoelectric material 35, with rods 25 disposed on the sheet. In the exemplified device, the rods and sheet are made from a single layer of the same piezoelectric material; however, the rods can alternatively be deposited onto the sheet and made from a different material, including any dielectric, metallic, or piezoelectric material. The generation of stopband and passband does not require the rods to be piezoelectric. Any periodic distribution of rods can generate the desired perturbation of the modes that allows the formation of the bands. Therefore, non-piezoelectric rods will still perturb the entire mechanical behavior of the structure, perturbing the propagation features of acoustic waves travelling along the ADL. Input and output terminals 40 are deposited on the piezoelectric sheet.

The propagation wavevectors of both longitudinal and shear modes (k_{eff}) become imaginary in certain frequency bands, creating regions where the propagation of real energy is no longer possible. This also allows to manipulate the wave speed of both longitudinal and shear modes, providing the means to slow the acoustic propagation down when operating within any passbands. The analytically derived trends of the propagation vector (k_{eff}) and acoustic transmission coefficient (T) of to the exemplified device were estimated following the procedure discussed in and are also shown in FIGS. 6C and 6D. As evident from FIG. 6D, the device exhibited wide acoustic passbands centered around four frequencies of interest. It should be noted that the electrical bandwidth of the ADL was lower than the bandwidth of T, being ultimately set by the Bode-Fano limit relative to the ADL's electrical matching.

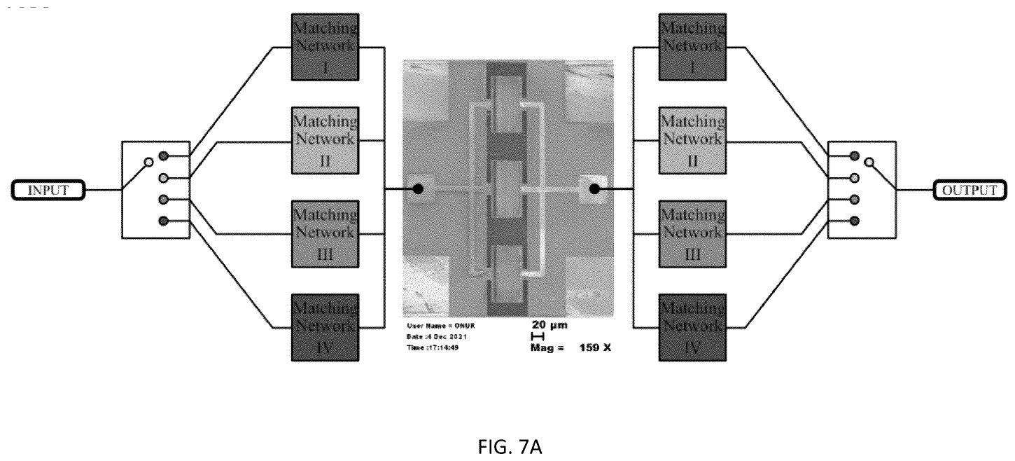

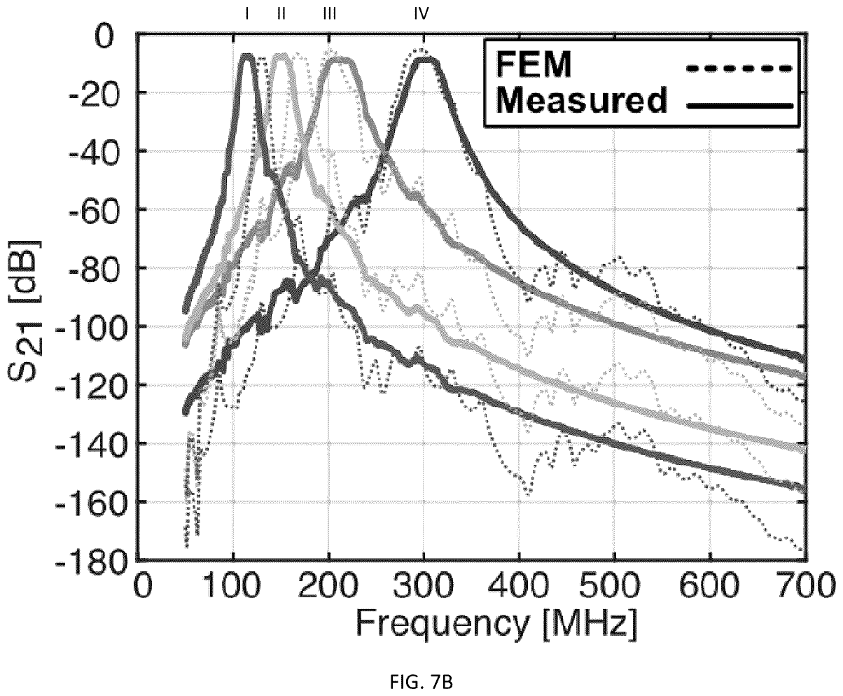

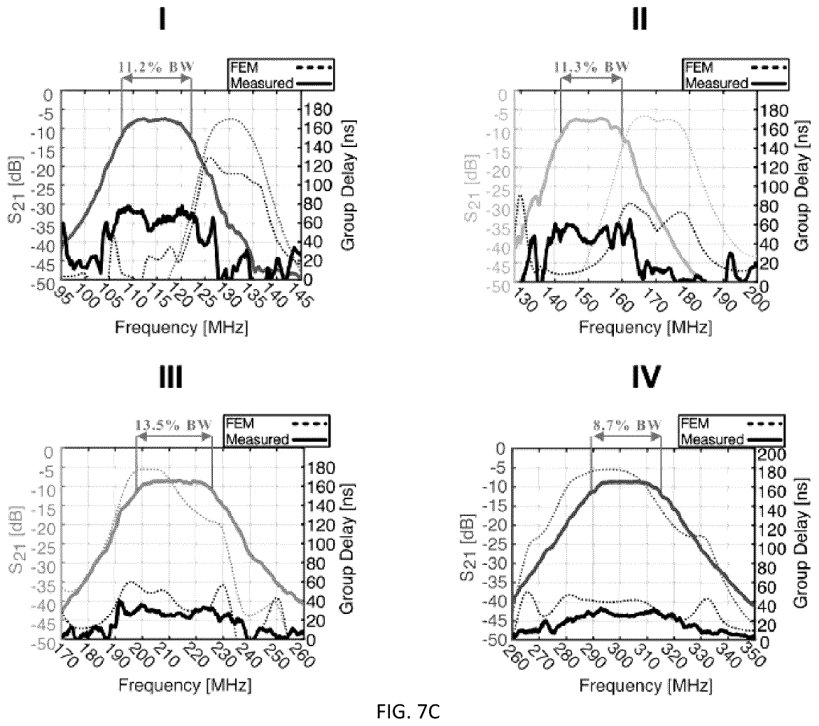

A system including the three array ADL described above and four alternate switchable matching networks was both simulated and fabricated. The matching networks for both simulation and measurement of responses were 50Ω and included three inductors with quality factors (Qs) of lower than 100 and one capacitor. FIG. 7B shows the simulated and measured responses of the ADL system of FIG. 7A using the different passbands. FIG. 7C shows expanded views of the data for the FEM-simulated insertion loss and group delay for each of the four passbands shown in FIG. 7B. The ADL operated within four different passbands centered around 115 MHz, 150 MHz, 210 MHz, and 300 MHz. The 3 dB fractional bandwidth of each passband was 11.2%, 11.3%, 13.5%, and 8.7%, with a minimum recorded loss of ˜8 dB. The measured group delay varied between ˜70 ns and ˜30 ns. The large loss is believed due to excessive amounts of electrical loading and can be improved by further optimizing the metal routing of the ADL.

The data described above demonstrate that the present technology provides frequency reprogrammable ADLs with up to 13.5% 3-dB fractional bandwidth and operable at four different frequencies (such as 115 MHz, 150 MHz, 210 MHz, and 300 MHz), each one corresponding to the center frequency of an acoustic passband generated by the metamaterial structure. This frequency re-programmability, which is achievable with selection of suitable matching conditions and is enabled by the unique dispersion features of the metamaterial structure, which is not present in any ADLs based on LW or SAW. ADLs based on LW or SAW cannot achieve frequency re-programmability.

In addition to the frequency programmability feature shown above, the present technology has several novel and useful features and advantages. The ADL devices of the present technology use wideband input and output transducers to radiate and receive an acoustic wave. The transducers separate a corrugated piezoelectric structure forming an acoustic metamaterial. This structure generates passbands for the propagation of shear-vertical (SV) modes characterized by much wider bandwidths than achievable through any existing counterparts. The ADL and systems including it can be formed by arrays of identical devices so as to achieve an easier and more performant electrical matching when connected to any electrical system. The center frequency of the ADL can be set lithographically by simply varying the geometry of the unit-cell forming the acoustic (piezoelectric) metamaterial and based on the known properties of the material.

The presently disclosed ADL devices and systems surpass the previous material-limited values of bandwidth and IL achieved by conventional ADLs. The ability to engineer the acoustic dispersion of the ADL makes the ADL ideal to form the delay lines needed by any self-interference cancellation feature in full-duplex RF systems. The ADL does not need any patterning of the bottom metal plate underneath the required piezoelectric layer. This is an important advantage over previous ADLs, which require patterning of the bottom metal plate, even though this significantly degrades the quality of the piezoelectric film. The present ADL achieves a group velocity that is exceptionally slow (nearly 1000 m/s). The ability to achieve such a slow speed is particularly relevant in applied physics, where classical or quantum wave-matter interaction is of great interest. When a piezoelectric material like AlN or AlScN is used, the present ADL can be manufactured together with the rest of the complementary electronics on a chip, ensuring the highest possible performance and reduced manufacturing costs compared to use of other materials. The ultra-low form factor of the present ADL makes it possible to achieve exceptionally miniaturized RF systems, with benefits in terms of cost per fabricated unit within a mass-scale production framework.

The present ADL can be used to fabricate any type of passive RF component, similarly to electromagnetic ADLs, but with the ability to reduce the form factor by 100000-fold or more. The ADL can be used as the required delay element in self-interference cancellation networks, such as those needed to practically use any full-duplex radio in uncontrolled electromagnetic environments. The ADL can be used to make filter components with exceptional bandwidth that surpass by a great extent what was possible to attain previously using on-chip counterparts. The present technology can be used to develop ADLs for on-chip RF components in wideband radios, such as those needed for 4G-to-5G communication. It also can be used to make RF components for space applications, as well as to make exceptionally slow-wave guiding structures for future quantum devices and systems.

### Application of Acoustic Metamaterials to CMR

The above described acoustic metamaterial (AM) structure is based on a forest of rods attained by corrugating thin AN/AlScN films. As described above, applying such AM structure in the active region of a bulk-acoustic-wave (BAW) resonator has led to a new class of resonators, labeled as Two-Dimensional-Resonant-Rods (2DRRs), with augmented kt². In addition, as described below, using two sets of AM structures (e.g., 2D rod arrays or even similar 2DRRs) along the lateral sides of the active region of an Al₇₂Sc₂₈N CMR, in addition to the conventional thin anchors placed along y, permits generation of an acoustic stopband preventing the piezo-generated vibration from leaking laterally, enabling even higher Qs than those attained by conventional designs with lateral sides being profiled with hard-etched sidewalls. Even more, such AM structures provide a much larger path for the heat generated in the resonator's active region during its motion to flow into the substrate, providing the means to reduce any thermal nonlinearities with respect to those affecting the performance of conventional AlScN CMRs that use only two tiny anchors along the y-axis.

Principles of Operation

In accordance with the present technology, the use and operation of CMRs using AMRs along their lateral sides (CMR^{AM}) permits such CMRs to overcome the trade-off that currently exists in the design of CMRs between anchor losses and power handling.

A. CMRs, Anchor Losses and Thermal Nonlinearities

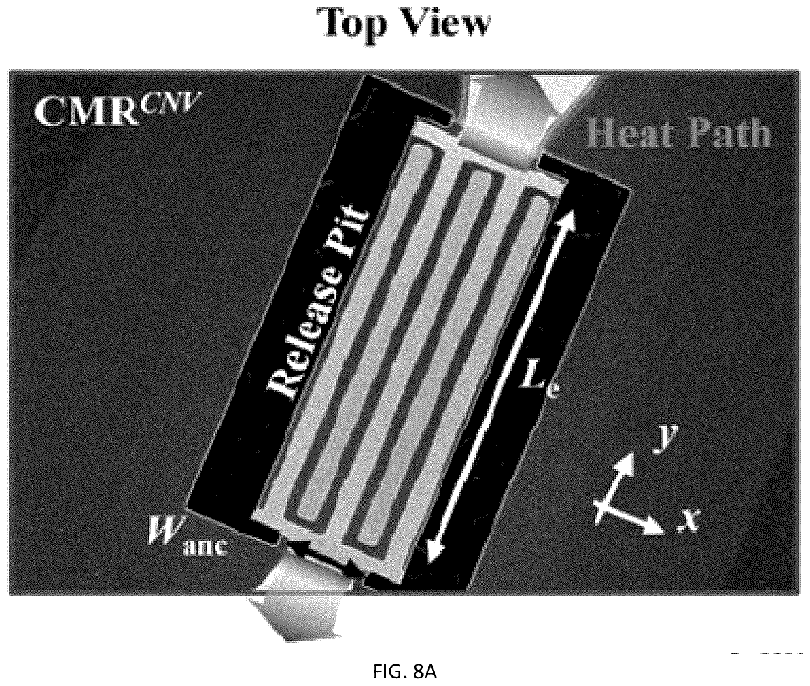

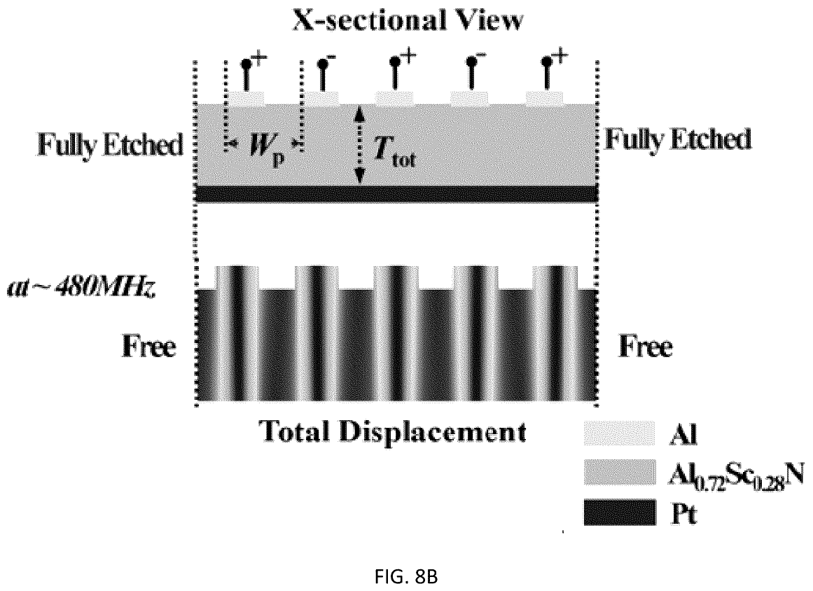

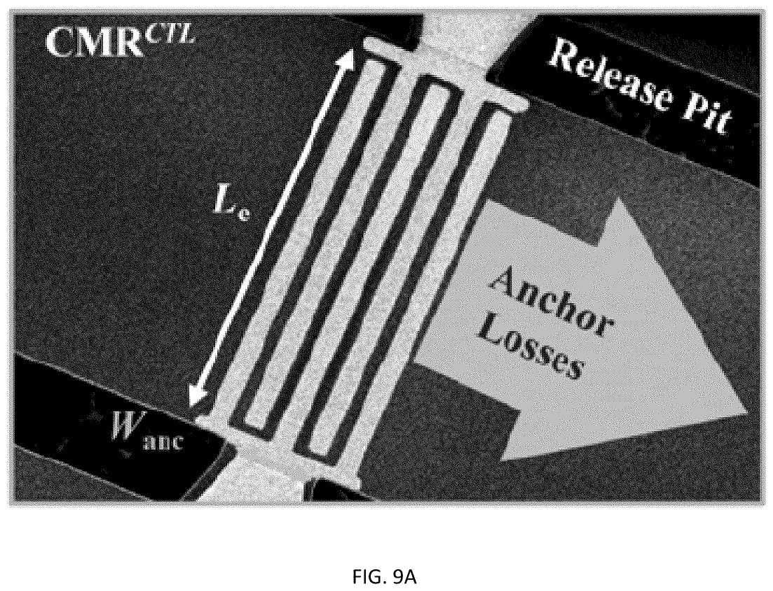

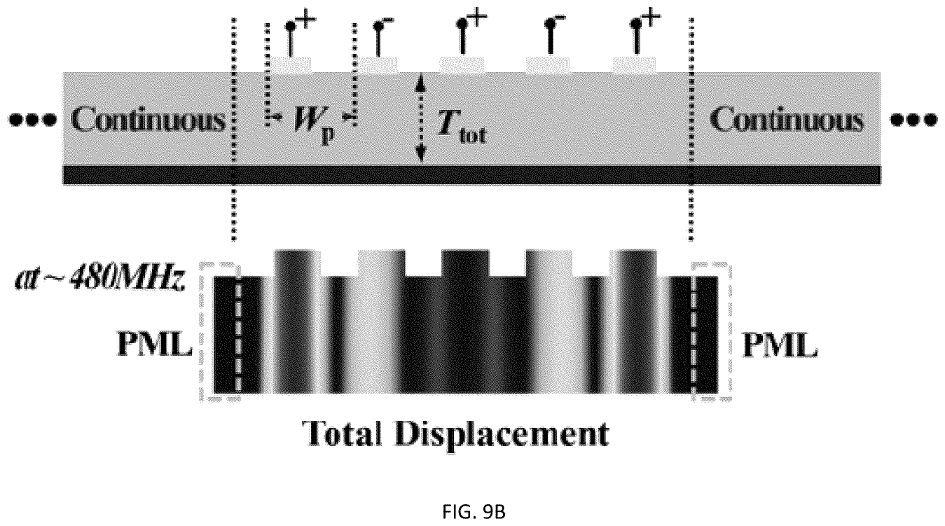

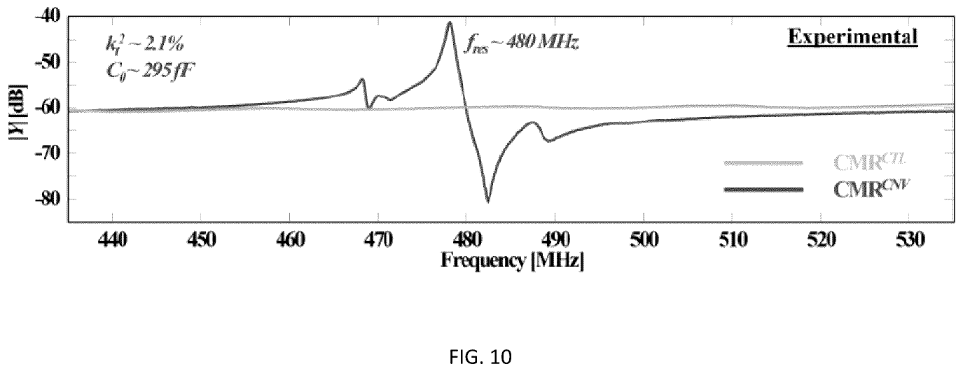

In their most used design topology, CMRs are formed by a piezoelectric plate sandwiched between one interdigitated metal structure (IDT) and a floating metal plate. The IDT structure is responsible for the transduction of a longitudinal mode of vibration from its generated electric field in the piezoelectric plate. In particular, when relying on c-oriented hexagonal AlN thin-films, CMRs excite a longitudinal mode of vibration noted as contour-mode in their suspended membrane, which coincide with the S₀ Lamb-wave mode in the limit of λ, being much larger than the CMRs' thickness. In order to piezoelectrically transduce such contour-mode, a standing wave must form within CMRs' active region and along CMRs' lateral direction. Usually, such transduction requires the lateral boundaries of the membrane to be cut-off and the structure to be suspended in order to prevent the generated acoustic wave from leaking into the substrate. For example, referring now to FIG. 10, comparing the electrical response of a conventional CMR (see CMR^{CNV} as shown in FIGS. 8A-8B) having such etched lateral sides with a control CMR (see CMR^{CTL} as shown in FIGS. 9A-9B) having un-etched lateral sides left fully-attached to the substrate, it is apparent that, for the CMR^{CTL} having the un-etched lateral sides, Q, becomes too small to be able to electrically detect any resonance.

As a result, CMRs have historically recurred to fully etched lateral sides as in CMR^{CNV} of FIGS. 8A-8B. However, having only the y-anchors to structurally support such CMR^{CNV} heavily shrinks the path available for heat generated upon vibration to flow into the substrate. In fact, the rate of heat-flow into the substrate for any CMR is inversely proportional to an equivalent thermal resistance (Rₜₕ), which grows larger as anchoring perimeter decreases. Larger Rₜₕ values relate to larger temperature increases in the CMR's body which, in turn, induces larger thermal nonlinearities and degrades the CMR's power handling performance. These challenges are compounded because, while using AlScN or other materials that offer a significant performance improvement in terms of kₜ² with respect to AlN, such materials are characterized by a thermal conductivity that is much smaller than AlN. For example, the thermal conductivity of AlScN is up to two orders of magnitude smaller than AlN. As a result, for any selected anchoring strategy, CMRs made with high kₜ² piezoelectric materials, such as AlScN, exhibit worse thermal linearity than their AlN counterparts.

This represents a significant challenge in providing new CMR designs granting improved thermal linearity without affecting the achievable electromechanical performance. In particular, this challenge is critical and unavoidable in that the acoustic motion to be leveraged by the CMR and the heat accumulation to be minimized in the CMR's body are both originated from the same elastic vibrations. Meanwhile, the complex ballistic process of heat and acoustic phonons that may impair the heat conduction only occurs when the characteristic dimension of the vibrating structure becomes smaller than the mean free path (MFP) of heat phonons.

Therefore, when analyzing CMRs' ability to dissipate heat, the heat conduction from CMRs' active regions into the substrate can reasonably be treated as a diffusive process which obeys Fourier's law. Once this assumption is made, it can be understood that, to improve the thermal linearity of CMRs, the total anchoring perimeter needs to be increased without leakage of the acoustic wave into the substrate. As discussed herein, the present technology achieves this outcome by introducing anchors along the lateral edges of the CMR which are characterized by a frequency selectivity that inhibits the propagation of acoustic waves to prevent any undesired acoustic leakage. This is key to reducing Rₜₕ while preserving a high [symbol] ₛ.

As described herein, the present CMR^{AM} technology provides a set of two AMRs placed along the lateral sides of CMRs to meet this need. As also described herein, CMR^{AM} offer significant advantages compared to classic MR-topologies.

B. Acoustic Metamaterials-Based Reflectors

Due to exotic dispersion features of AMs, they are advantageously able to generate passbands and stopbands for acoustic wave manipulation. In the present technology, those properties are exploited via the adoption of AMRs to generate stopbands that can help improve thermal linearity without affecting the achievable electromechanical performance. Like the AMs-based structures associated with the ADLs described hereinabove, AMRs are formed by a forest of piezoelectric rods built on a thin plate. In some embodiments, the plate and the rods can be formed by partial etching the same AlScN plate used as active material in the CMRs' body.

Referring now to FIGS. 11A-11C, CMR^{AM} 1100 in accordance with various embodiments can include AMRs 1110 generally comprising 2D rod arrays directly built along opposing lateral sides of an active region 1160 of the CMR^{AM} 1100 by cascading a chain of each AMRs' 1110 unit-cells 1101. These arrays are best shown in FIGS. 11A and 11B, which illustrate an annotated SEM top view image and a cross-sectional side view of a CMR^{AM} 1100 and its respective active region 1160 and AMRs 1110.

FIG. 11C illustrates the structure of a unit-cell 1101 of an AMR 1110. As shown, the unit-cell 1101 is formed by an unpatterned bottom conductive plate 1115 (e.g., a Pt-layer as shown) underneath a corrugated piezoelectric layer 1135 (e.g., an AlScN film as shown) to form a rod 1120 flanked by partial trenches 1130.

In the exemplified device, the rods 1130 and trough 1130 are made from a single layer of the same piezoelectric layer 1135. However, the rods 1130 can alternatively be deposited onto the piezoelectric layer 1135 and made from a different material, including any dielectric, metallic, or piezoelectric material. The generation of stopband and passband does not require the rods to be piezoelectric. Any periodic distribution of rods 1130 can generate the desired perturbation of the modes that allows the formation of the bands. Therefore, non-piezoelectric rods 1130 will still perturb the entire mechanical behavior of the structure, perturbing the propagation features of acoustic waves travelling along the AMR 1110.

The cascading a chain of each AMRs' 1110 unit-cells 1101 generally forms a 2D rod array (e.g., 2D resonant rod arrays, also referred to as “2DRRs”) containing a group of one or more unit cells 1101 with the rods 1120 in parallel arrangement and separated by the troughs 1130. Each AMR 1110 can include any number of one or more unit cells including, for example, between one (1) to 11 unit cells 1101 or more. In addition, although the CMR^{AM}s 1100 tested and described herein include AMRs 1110 having equal numbers of unit cells 1101, it is also possible to design CMR^{AM}s having unequal numbers of unit cells.

As explained above and best shown in FIG. 11A, this configuration maintains the active region's 1160 lateral connections to the substrate 1105 in order to conduct the heat away from the conductive plate 1115 while simultaneously constraining the acoustic energy in the active region 1160.

The active region 1160 can include one or more IDTs 1140 patterned on a portion of the piezoelectric layer 1135 located within the active region 1160. The active region 1160 can be disposed between two y-anchor structures 1150 and the IDTs 1140 will typically be connected, via conductive paths through the y-anchors to conductive pads on the adjacent chip (not shown). The IDTs 1140 can be any conductive material 1145 such as, for example, Pt, Al, Mo, Cr, Ti, W, or Cu. The y-anchor structures 1150 can be made of a beam of the piezoelectric layer 1135 (e.g., AlScN as shown) sandwiched between two metal or conductive layers.

To verify the AMRs' ability to inhibit the propagation of the contour-mode excited by CMRs, it was necessary to investigate the AMRs' wave propagation characteristics. In this regard, Tzung-Chen Wu et al. analyzed the Lamb wave dispersion of a grooved structure and found that the topology added by rods or pillars that are comparable or even thicker than their supporting plate can dramatically change the velocity of the Lamb modes propagating along the plate. Such hybridization-processes can lead to the generation of multiple Bragg bandgaps (BGs) in the acoustic transmission spectrum relative to incident longitudinal modes exhibited by such corrugated AMs-based structure. Also, such BGs become wider as thicker rods are used due to a phenomenon of mode-coupling involving multiple Lamb modes. With that understanding of the potential acoustic dispersion features, a Finite Element Model (FEM) was used to verify whether AMRs placed along the lateral sides can really generate large BGs constraining the vibration produced by CMRs along their lateral direction.

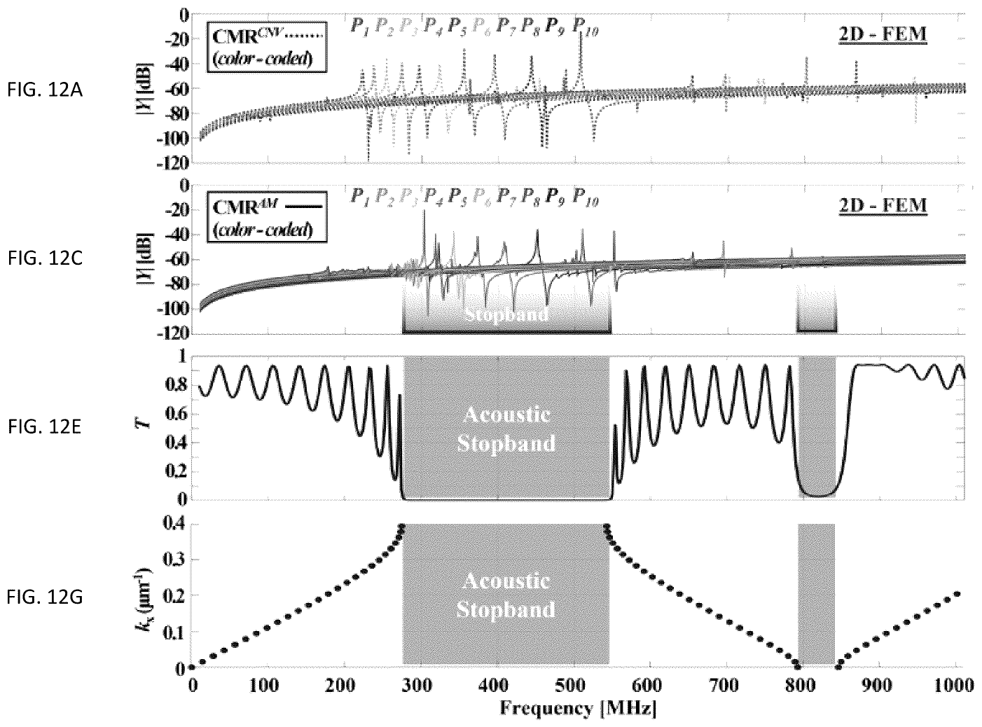

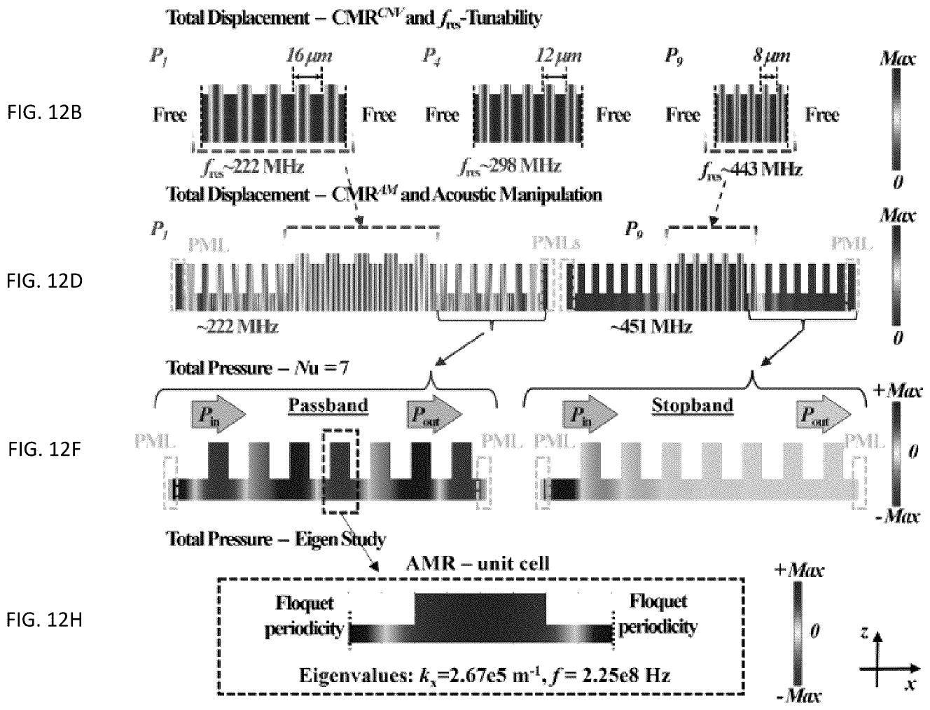

Referring now to FIGS. 12A-12H, during this FEM investigation, ten CMR-pairs characterized by different IDT pitches (Wₚ, labeled as P₁-P₁₀) were defined. In each pair, one device (labeled as CMR^{AM} and shown, for example, in FIGS. 12C-12D, 12F, and 12H) was implemented with AMRs formed by seven unit-cells with the same numerically optimized geometry used in the experiments described herein, while the other (labeled as CMR^{CNV} and shown, for example, in FIGS. 12A-12B) used fully-etched, stress-free lateral boundaries.

FIG. 12A illustrates the admittance response of the simulated CMR^{CNV} devices, each one having a different fᵣₑₛ value set by its IDT pitch (Wₚ) [Wₚ is tuned from 6 μm (P₁) to 15 μm (P₁₀)]. In FIG. 12B, examples of the at-resonance total-displacement modeshapes are illustrated for the CMR^{CNV} devices with Wₚ respectively equal to P₂, P₅ and P₉. The admittance responses for CMR^{AM} devices, employing the same Wₚ values used for the analysis of the CMR CNV devices, are illustrated in FIG. 12C. Comparing FIG. 12C against FIG. 12A, it is apparent that, unlike the CMR^{CNV} devices, the CMR^{AM} devices do not show any strong resonances for frequencies below 280 MHz. Additionally, the CMR^{AM} devices show clear responses when their resonance falls into the 280-550 MHz range.

In order to understand the origin of such a frequency-selective electrical response, it is useful to look at the at-resonance total displacement modeshapes relative to two CMR^{AM} devices, with resonance frequencies below and above 280 MHz respectively. For this purpose, FIG. 12D illustrates different total-displacement modeshapes for the CMR^{AM} devices with Wₚ equal to P₂ and P₉. As shown, the CMR^{AM} device with Wₚ equal to P₉ exhibits a rapidly decaying displacement profile along AMRs' length, thus showing negligible anchor losses. In contrast, the CMR^{AM} device with Wₚ equal to P₂ shows a significant displacement along the AMRs' length, justifying the presence of unsustainable anchor losses that ultimately render the device's admittance almost undetected. The cause of such a difference has been studied through FEM by simulating the acoustic transmission (T) frequency-response of the same AMR-structure used by the analyzed CMR^{AM} device when considering a longitudinal wave incident upon one of AMR's lateral sides.

Interestingly, as shown in FIGS. 12E-12F, a region of zero transmission exists covering the entire 280550 MHz range, thus explaining the ability to confine the acoustic energy within their cavity that all CMR^{AM} devices operating within such frequency range exhibit. In addition, another narrower zero-transmission frequency range exists, covering the ˜800850 MHz band. A large transmission is instead found across the remaining portion of the analyzed spectrum. A set of total displacement modeshapes extracted from this latter analysis is provided in FIG. 12F, showing the total pressure distribution for two different frequencies of the incident wave. As shown, when an incident acoustic wave has a frequency falling out of the two zero-transmission bands, it can propagate through the AMR. Differently, when the incident wave has a frequency included in such bands, it cannot propagate along the AMR, decaying exponentially along its length.

In order to identify the origin of the AMR's zero-transmission bands, an eigen study was performed through FEM by using one AMR's unit-cell and by applying Floquet periodic conditions (FPCs) along its lateral boundaries. The AMR's computed 1-dimensional Bloch diagram within the first Brillouin zone (positive half) is shown in FIGS. 12G and 12H, capturing the wavevector (kₓ) of the contour-mode vs. frequency. As shown, this analysis confirmed that the two zero-transmission bands found in the previous acoustic FEM investigation of the considered AMR-structure originate from two acoustic BGs that cover exactly the same bands occupied by the zero-transmission regions in FIG. 12E. As already mentioned, another feature that emerged from this FEM investigation is the existence of a second BG, centered around twice the center frequency of the first one. In line with what was previously observed, the origin of such a second BG is to be attributed to the rods, which generate new regions of inhibited propagation when their thickness is comparable or higher than the thickness of the supporting plate.

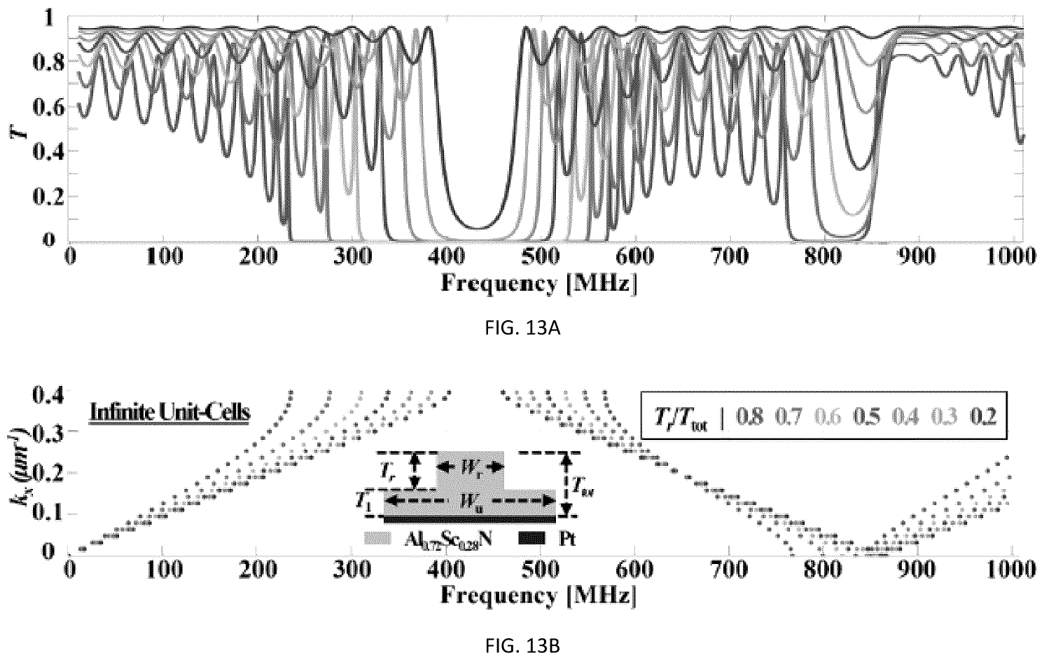

This has been confirmed by simulating, by FEM, t and kₓ vs. frequency for increasing rod-thicknesses (Tᵣ) as shown in FIGS. 13A and 13B, assuming the same in-plane AMR's unit-cell geometry as shown, for example, in FIGS. 12D, 12F, and 12H. As shown, as the ratio of Tᵣ to the thickness of AMR's AlScN plate (T₁) increases above ten percent, the main AMR's BG starts widening and the second and narrower BG starts forming. It is speculated that the near 2:1 correlation between the center frequencies of the identified BG can be attributed to an elastic energy storing effect becoming more significant as larger corrugations of the AlScN layer are formed. It is worth mentioning that a similar effect occurs in the MRs used by Surface Acoustic Wave (SAW) resonators operating at frequencies lower than the cutoff frequency for BAW-propagation. In such a scenario, in fact, MRs exhibit a total-reflection at twice the fundamental Bragg-frequency.

C. AMRs vs. Planar Metal Reflectors

The inventors also conducted and analyzed a performance comparison between AMRs and metal reflectors (MRs). Historically, MRs have been widely used as acoustic reflectors for SAW resonators and transversal filters. They are formed by gratings of metallic strips that create a spatial modulation of the acoustic impedance (Z_{ac}) along the SAW propagation direction. Such a Z_{ac}-modulation produces a BG that ultimately inhibits the lateral propagation of Rayleigh waves along MRs' width.

MRs can also be used along the lateral sides of AlN Lamb wave resonators to avoid etching their sides. However, the perturbation of the Lamb modes' dispersion properties caused by the use of MRs can be significantly different from the one generated by AMRs. Therefore, it is important to compare AMRs' and MRs' performance with respect to their ability to reflect the acoustic energy produced by CMRs and to favor a heat-flow along the lateral direction. In particular, two key metrics need to be considered when comparing such two reflector-structures: the fractional width of their widest BG and their minimum size to ensure a strong enough confinement of the acoustic energy and, consequently, to maximize [symbol] ₛ.

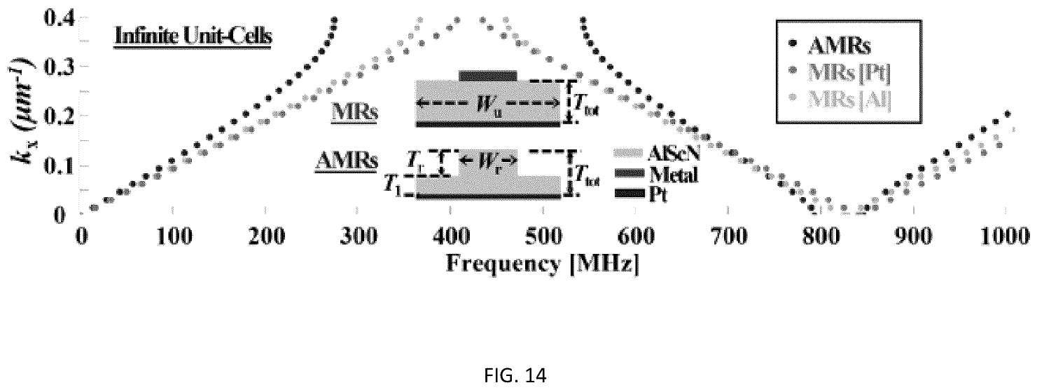

In order to compare AMRs vs. MRs, a set of FEM simulations was used. First, the dispersion curve for the contour-mode was extracted when considering a MR formed by a 120 nm-thick aluminum layer (e.g., the same top-metal thickness and material used in the AMR experiments) and having the same pitch used by the AMR considered in FIGS. 12C-12H. As shown in FIG. 14, the AMR's widest Bragg bandgap (BG) has a bandwidth that is more than twice the size of the analyzed MRs' BG. This has two crucial practical consequences. First, when using AMRs as lateral anchors of CMRs they ensure performance that are less sensitive to undesired process-variations, which often cause shifts in the center frequency of the BG with respect to the originally targeted one. Second, the same pair of AMRs can be used to confine the acoustic vibration produced by a large pool of CMRs with different resonance frequencies. Obviously, this is important as it simplifies the complexity of the fabrication process required to manufacture multiple CMR^{AM} devices with different resonance frequencies on the same wafer.

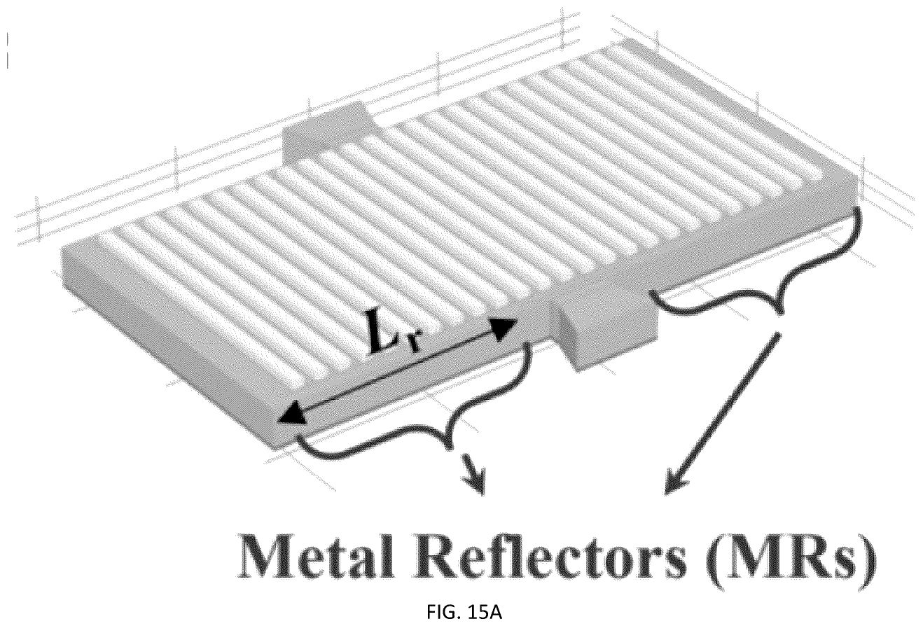

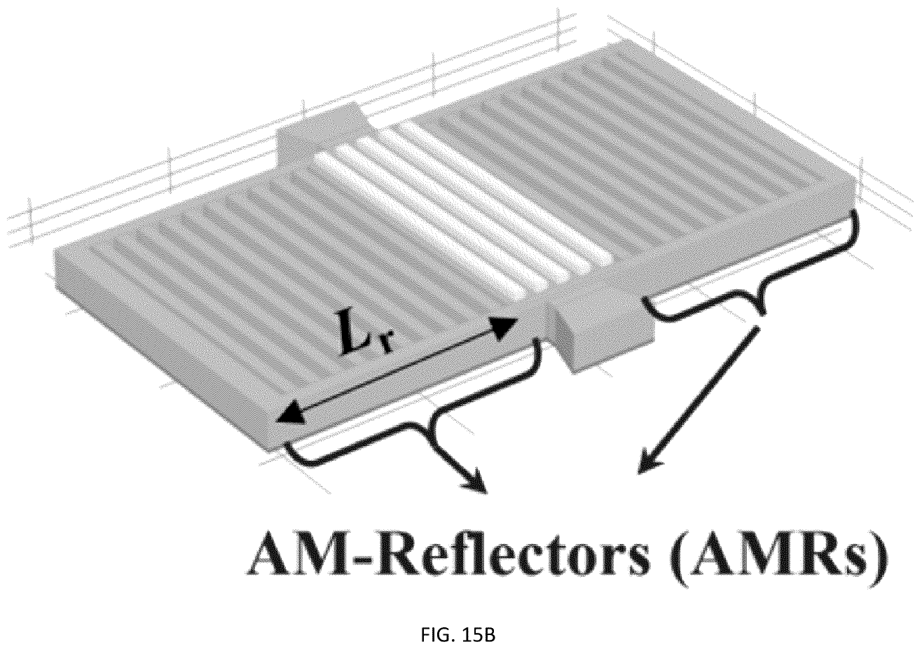

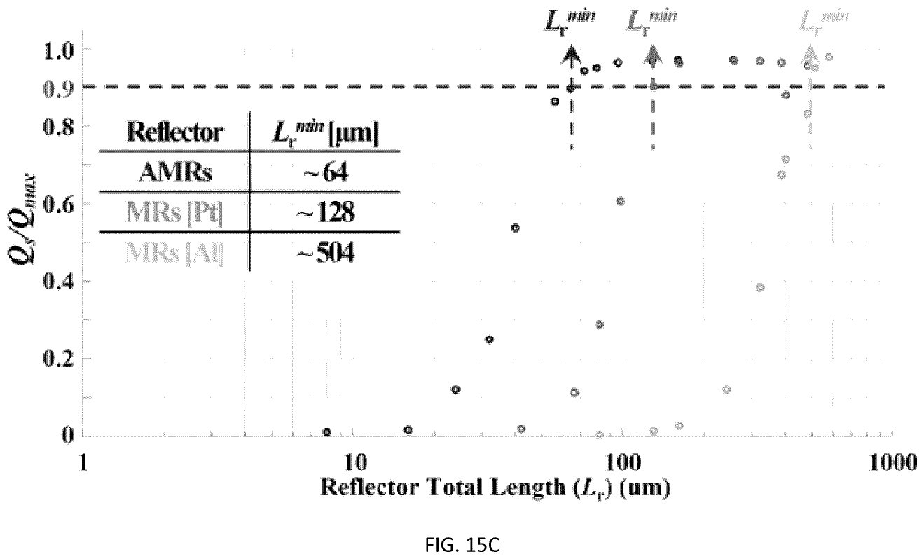

Another FEM simulation, illustrated in FIGS. 15A-15C, was run to estimate the minimum size (Lᵣ^{min}) of AMRs and MRs when used as lateral anchors in CMRs. In order to find Lᵣ^{min}, the FEM was used to extract the normalized distribution of the achievable [symbol] ₛ (normalized to an arbitrarily chosen intrinsic value, [symbol] ₘₐₓ, set to 10,000 in our FEM simulation) vs. the size of the AMRs or MRs used by a CMR to minimize the acoustic energy leakage. In this analysis, the CMR's fᵣₑₛ-value (#443 MHz) was assumed to be included in both the BGs formed by the analyzed AMR and MR structures. Then, Lᵣ^{min} was identified as the Lᵣ size ensuring normalized [symbol] ₛ-values equal to 0.9. For a fair comparison, MRs formed by Pt or Al were also considered here. It is worth mentioning that using aluminum to form MRs for CMRs is practically easier since CMRs generally use Al top-IDTs and no additional fabrication steps would be needed to build the MRs. However, Al offers relatively low values of reflectivity when placed on AlScN, thus being not the best material to use when targeting a MR design. In contrast, platinum offers a significantly larger reflectivity when placed on AlScN films. Yet, the use of platinum to form the top IDT of CMRs is not ideal due to the higher thermoelastic and ohmic dissipations that CMRs' Pt IDTs cause.

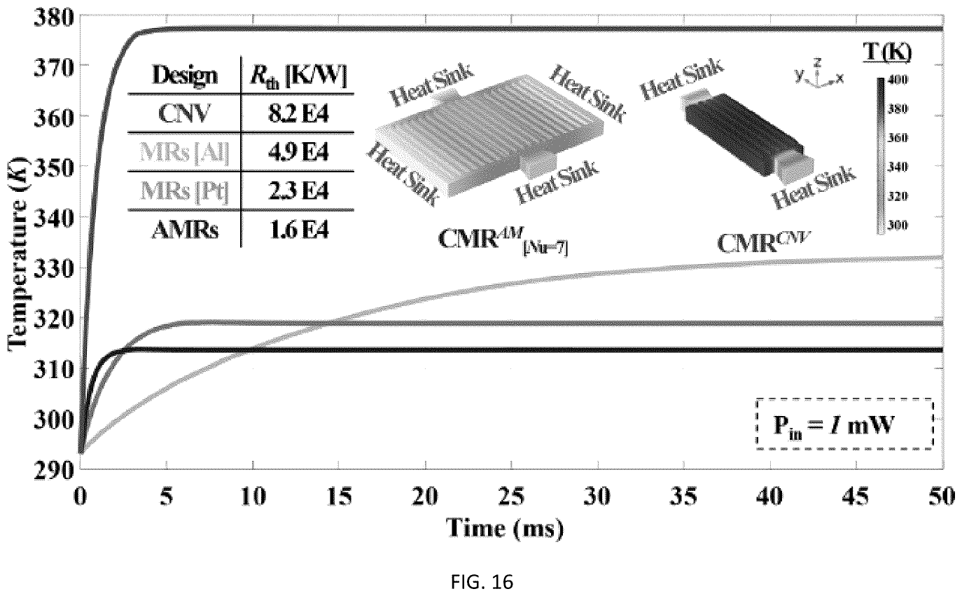

The simulation results, illustrated in FIG. 15C, clearly show that Lᵣ^{min} is significantly lower for AMRs than for MRs made of Pt or Al. Therefore, AMRs provide a more compact solution than MRs. This generates two key advantages. First, CMR^{AM} devices can be smaller than CMRs using MRs. Secondly and most importantly, due to their more compact size with respect to MRs, AMRs generate a shorter path for the heat generated into CMRs' active region upon vibration to flow into the substrate. This results into a lower Rₜₕ and, consequently, in lower thermal nonlinearities and higher power handling. As shown in FIG. 16, in order to demonstrate this feature, Rₜₕ was numerically computed for a CMR^{AM} device using the optimum number of unit-cells based on the calculated Lᵣ^{min}. Rₜₕ was also computed for two corresponding CMRs with the same design of the active region used by the CMR^{AM} device but relying on Pt and Al MRs, optimally-sized based on the calculated corresponding Lᵣ^{min} values found in FIG. 15C. Finally, as a reference, Rₜₕ was computed for a conventional CMR suspended exclusively through the y-anchors. For all these calculations, Rₜₕ was determined following Eq. 1 and by using the results of ad-hoc 3D-FEM thermal simulations predicting both the thermal time constant (τₜₕ) and the thermal capacitance (Cₜₕ) of the devices under-study. Among all the investigated devices, the CMR^{AM} device shows the lowest Rₜₕ.

τₜₕ=Rₜₕ·Cₜₕ (1)

The identification of Rₜₕ is particularly important as it facilitates prediction of which devices in a pool of devices are expected to be more or less affected by thermal nonlinearities. In fact, the nonlinear Duffing coefficient (α_{A-f}) capturing the distortion of CMRs' admittance response caused by thermal nonlinearities is directly proportional to Rₜₕ. Thus, regardless of which lateral anchoring strategy is used to achieve the highest possible quality factor value, the thermal linearity of a CMR will be ultimately set by Rₜₕ.

### Experiments and Analysis

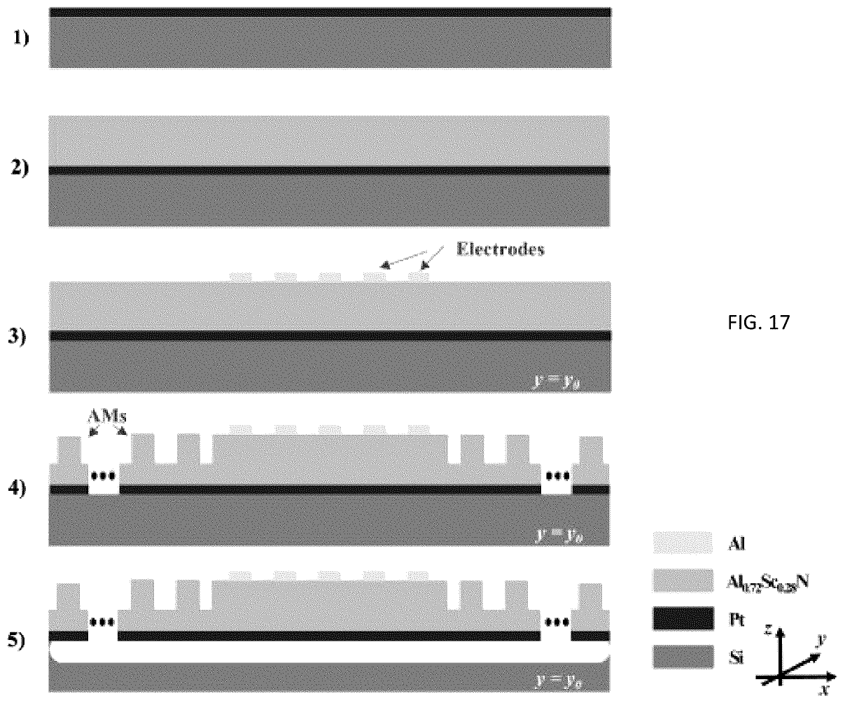

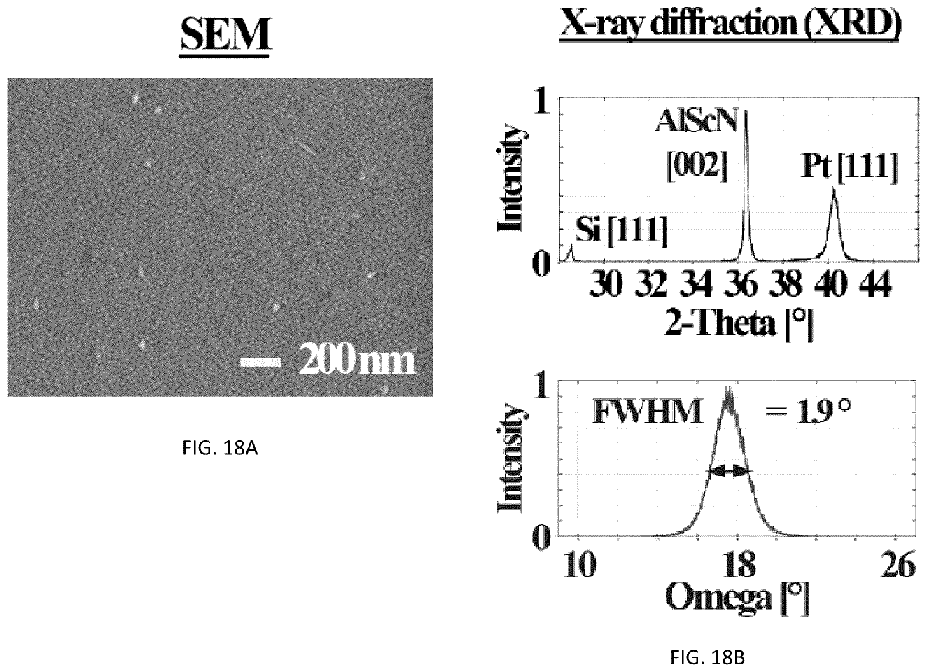

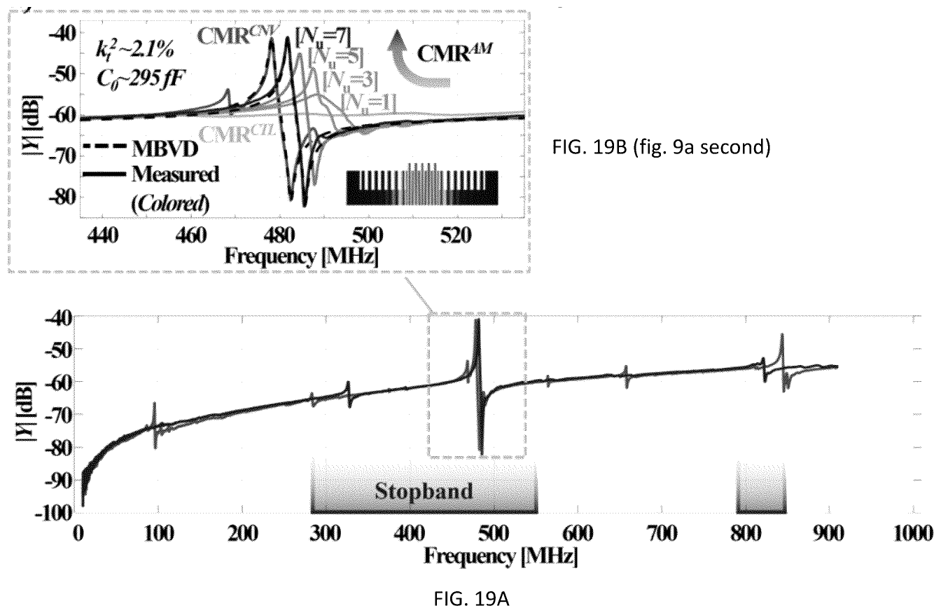

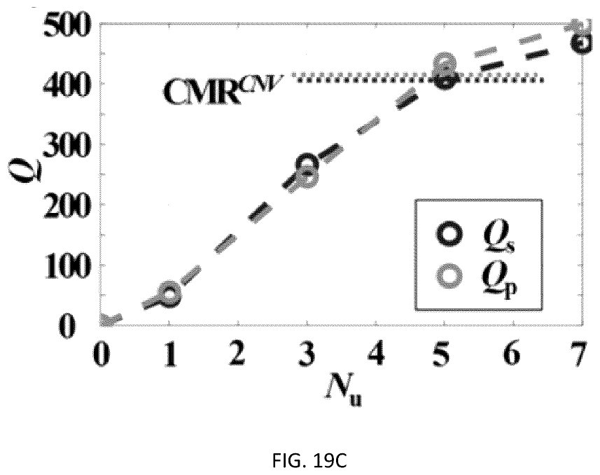

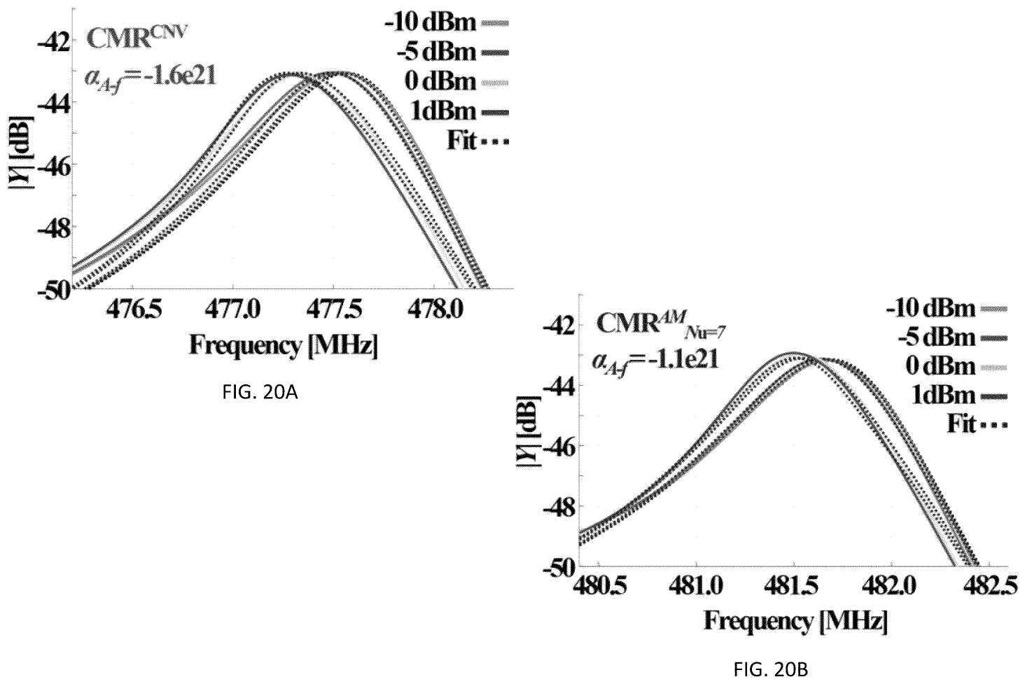

To validate the new reported AlScN CMR^{AM} design using AMRs, six sets of lateral-field-excited (LFE) Al_{0.72}Sc_{0.28}N CMRs with identical active regions, material composition and y-anchor width were built and tested. In this study six different lateral anchoring strategies were explored. One configuration (CMR^{CNV}) was a conventional CMR design with lateral sides fully etched to form stress-free boundaries. Another configuration (CMR^{CTL}) was designed with the AlScN plate un-etched along the CMR's lateral sides. The four remaining configurations (CMR^{AM}_{Nu=1,3,5,7}) were designed with AMRs along the CMRs' sides formed by 1, 3, 5 and 7 unit-cells respectively, and with an identical numerically optimized unit-cell geometry (Tᵣ=350 nm, Wᵣ=4 μm, Wᵤ=8 μm). The unit-cell geometry used for these experiments is the same unit-cell geometry relied on in the simulations for the CMR^{AM}_{Nu=7} considered in FIGS. 12A-12H. All the devices were fabricated on the same wafer by using the fabrication process summarized in FIG. 17. In particular, starting from a Si-substrate, a 5 nm/60 nm Ti/Pt layer was deposited (and patterned under the pads) as shown in step 1 of FIG. 17. Then, a 500 nm AL_{0.72}SC_{0.28}N film was deposited, as shown in step 2 of FIG. 17, by co-sputtering Al and Sc at 350° C. in a nitrogen plasma. The achieved effective concentration of Sc-doping was controlled by individually tuning the power levels on the Al and Sc targets. Next, in step 3 of FIG. 17, a room-temperature sputtering and lift-off step was performed to pattern a 100 nm-thick Al layer, forming the IDTs of all CMRs under-investigation. Later, a 200 nm-thick Au layer was deposited to form the electrical routing traces and probing pads (this step is not shown in FIG. 17). Then, a SiO₂-layer was deposited via Plasma Enhanced Chemical Vapor Deposition (PECVD) and patterned through Ion Coupled Plasma Reactive Ion Etching (ICP-RIE) to create an hard-mask for etching the Ti/Pt/Al_{0.72}Sc_{0.28}N stack and open the release pits (this step is also not shown in FIG. 17). After the release pits were created, a second patterning of the same SiO₂-layer was performed to generate the hardmask required to form the AMRs' rods as shown in step 4 of FIG. 17. Finally, the remaining SiO₂ was removed through dry-etching and all devices under investigation were released by an isotropic Si-etch in XeF₂, as shown in step 5 of FIG. 17. FIGS. 18A and 18B illustrate a top-view scanning electron microscopy (SEM) image and an X-ray diffraction (XRD) 2-theta and Omega scan of the Al_{0.72}Sc_{0.28}N film to demonstrate the low density of abnormally oriented grains (AOGs) and the good crystallinity achieved for the Al_{0.72}Sc_{0.28}N film. A SEM picture of CMR^{AM}_{Nu=7} is shown in FIG. 11A.

After building the devices, their admittance responses were measured. The measured admittance magnitude (|Y|) for the best devices tested for each analyzed configuration is shown in FIGS. 9A and 9B. In particular, FIG. 9A shows |Y| from 435 MHz to 535 MHz, within the widest BG of the adopted AMRs (see FIG. 12G). Two curves correspond to the responses of CMR^{CNV} and CMR^{CTL}. The remaining four curves correspond to the responses of the measured CMR^{AM}_{Nu=1,3,5,7}. The at-resonance admittance magnitude proportionally grows with the adopted number of unit-cells, indicating an increase of [symbol] ₛ. Not surprisingly, even the quality factor ( [symbol] ₚ) exhibited by CMR^{AM}_{Nu=1,3,5,7} at the parallel resonance frequency shows an increase vs. the number of unit-cells. In fact, the [symbol] ₚ-value of any CMR generally matches closely to the CMR's mechanical (e.g., unloaded) quality factor ( [symbol] ₘ) and it is mainly limited by anchor losses for CMRs operating below 1 GHz.

The measured trends of [symbol] ₛ and [symbol] ₚ vs. the number of unit-cells (e.g., Nᵤ) is illustrated in FIG. 9C. This trend was generated by testing and averaging the measured quality factor values relative to three devices for each configuration. Also, the quality factor values relative to Nᵤ equal to zero in FIG. 9B refer to the CMR^{CNV} devices, whereas the [symbol] ₛ and [symbol] ₚ values of CMR^{AM} are indicated with the indicated dashed lines. Interestingly, CMR^{AM}_{Nu=7} appears to exhibit even higher quality factor values than CMR^{CNV}. It is speculated that such boosted performance may be attributed to CMR^{AM}_{Nu=7}'s lower anchor losses along the y-direction than CMR^{CNV}. Such a loss-reduction may be enabled by a weaker mode-conversion experienced by CMR^{AM}_{Nu=7} along its not straight partially etched lateral sides with respect to CMR^{CNV}.

A wider frequency-span for |Y| is shown in FIG. 9B for CMR^{AM}_{Nu=7} and CMR^{CNV}. As expected based on the analyses illustrated in FIGS. 12A-12H, while CMR^{CNV} shows strong spurious modes in the passbands of the AMRs used by CMR^{AM}_{Nu=7}, the unique dispersion features of AMRs render these modes almost undetected in CMR^{AM}_{Nu=7}. This further confirms that AMRs generate frequency-selective boundary conditions along CMR^{AM}_{Nu=7}'s lateral sides that are reflective only within AMRs' BGs.

Table I below includes a summary of the averaged [symbol] ₛ, [symbol] ₚ, kₜ², and FoM obtained for all tested devices and configurations. The adoption of AMRs along the lateral sides of CMR^{AM} devices does not degrade the achievable kₜ² with respect to what attained by CMR^{CNV}. As a result, the FoM of CMR^{AM}_{Nu=7} also exceeds the one of CMR^{CNV} by nearly fifteen percent.

TABLE I
Measured Electromechanical Performance for All Experimental
CMR Configurations, After Averaging Measured Results
from Three Experimental Devices Per Configuration

| Device | Qs | Qp | kt2 | FoM |
|---|---|---|---|---|
| CMR^{CNV} | 409 | 415 | 0.02 | 8.2 |
| CMR^{CTL} | 0 | 0 | — | — |
| CMR^{AM}Nu = 1 | 48 | 55 | — | — |
| CMR^{AM}Nu = 3 | 266 | 246 | 0.02 | 5 |
| CMR^{AM}Nu = 5 | 409 | 433 | 0.016 | 6.5 |
| CMR^{AM}Nu = 7 | 468 | 499 | 0.02 | 9.4 |

After completing the electromechanical characterization for the CMR-configurations under investigation, the thermal linearity of CMR^{AM}_{Nu=7} and CMR^{CNV} was assessed and compared. These assessments relied on the extraction of α_{A-f} for both configurations. For a fair comparison between CMR^{CNV} and CMR^{AM}_{Nu=7}, the extraction of α_{A-f} was performed by considering a CMR^{AM}_{Nu=7} device among those were fabricated with nearly the same at-resonance admittance magnitude of the best CMR^{CNV}. This choice, in fact, ensures that both devices under-test absorb the same amount of power, which is critical for comparing their nonlinear characteristics. During the measurements, the IF bandwidth (IFBW) of the input signal was maintained at 50 Hz to make sure that the sampling rate was much slower than the devices' Tth-values, thus ensuring that any measured nonlinear behavior was caused by thermal effects.

As shown in FIGS. 10A and 10B, the peak of the resonance in the admittance curves bends toward lower frequencies when increasing the input power level. This represents a key sign of the presence of thermal Duffing nonlinearities, which cause a softening-mechanism due to the temperature dependence of the AlScN Young's Modulus. The extraction of α_{A-f} was performed by relying on an equivalent nonlinear-MBVD (Modified-Butterworth Van Dyke) model, following a known methodology. Such a model replaces the conventional linear motional capacitance (Cm) of the resonator under-investigation with a charge-dependent one (Cm(q)) defined in Eq. 2 as:

Cₘ(q)=Cₘ·(1−α_{A-f}·q²) (2)

where q is the motional charge. Then, α_{A-f} was found by fitting the measured nonlinear admittance responses for both devices at different input powers. α_{A-f} was found to be −1.6E21 C⁻² for CMR^{CNV} and −1.1E21 C⁻² for CMR^{AM}_{Nu=7}. The fact that α_{A-f} is significantly lower for CMR^{AM}_{Nu=7} confirms the improved performance of the present technology, proving that CMR^{AM}_{Nu=7} suffers less from thermal nonlinearities than CMR^{CNV}.

### ADDITIONAL FEATURES AND BENEFITS

The present technology provides the first CMR (an Al_{0.72}Sc_{0.28}N CMR as built and tested) using a pair of acoustic metamaterials-based reflectors (AMRs) to laterally anchor the device along its main vibrational direction. Analysis, modeling, and experimentation verify that the use of AMRs enables ˜15% improved quality factors with respect to conventional CMR designs that rely on fully etched lateral sidewalls to define the resonant cavity. Moreover, using AMRs along the lateral sides of CMRs makes it possible to lower the thermal nonlinearities of CMRs. Such unique features, enabled by AMRs, advantageously provides improved electromechanical performance and power handling. In fact, the best AMR-using device tested and described herein exhibits a ˜30% improvement in the overall linearity and ˜15% improved figure-of-merit (FoM) with respect to its conventional counterpart. While the use of AMRs is shown and described herein in the context of obtaining higher performance and making practical the more widespread adoption of linear filters and oscillators based on AMR-using CMRs, the present technology can be used to improve performance in connection with any other resonator technologies, whether relying on AlScN or any other piezoelectric materials, particularly those having higher electromechanical coupling coefficients (kt²) than AlN.

More generally, the present technology improves the performance and linearity of MEMS and NEMS resonators by using the unique dispersive features of acoustic metamaterials, wherein the introduction of acoustic metamaterial lateral anchors improves the electromechanical performance and power handling of MEMS and NEMS resonators, outperforming all the existing approaches, including the adoption of Bragg reflectors or the use of stress-free boundaries.

Functionally, using two sets of such acoustic metamaterials (AM) anchor structures along the lateral sides of the active region of a MEMS or NEMS resonator generates an acoustic stopband preventing the piezo-generated vibration from leaking laterally. This ensures a maximization of the electromechanical performance of the MEMS or NEMS device by minimizing anchor losses and by maximizing the electromechanical coupling coefficient. Even more, such AM structures provide a new effective path for the heat generated in the resonator's active region during its motion to flow into the substrate, providing the means to reduce any thermal nonlinearities with respect to those affecting the performance of conventional MEMS or NEMS devices using only two tiny anchors along the y direction.

The technology provides the following novel and unusual features.
1. The present technology relies on acoustic metamaterials to inhibit the propagation of acoustic waves along undesired directions. As such, the suppression bandwidth is large enough to be immune from fabrication nonidealities;
2. The present technology permits efficient optimization of the performance of MEMS or NEMS resonators without requiring the large reflector structures needed by previous counterparts, like Surface Acoustic Wave resonators and Bulk Acoustic Wave resonators.
3. The present technology can be used independently on the resonator technology and the same metamaterial structure can be used to improve the performance of resonators operating at much different frequencies.

The technology offers the following advantages and improvements.
1. The metamaterial structure is effective, allowing to achieve optimal performance in a much narrower form factor. Even more, it can be manufactured with a simple fabrication process.
2. The metamaterial structure's response is immune from fabrication nonidealities, thanks to its wideband response.
3. The metamaterial structure permits attaining optimum performance while enabling a lower thermal resistance for the adopted resonator than what is possible in conventional designs. As such it can be key when a high Q is needed in conjunction with high power handling devices.
4. This technology can be applied to any possible resonators (electrostatic or piezoelectric) and when considering any existing piezoelectric materials, including those that can be manufactured on chip (e.g., AlN, AlScN, GaN, etc.).

The technology provides at least the following uses.
1. It can be used to improve the performance of existing Bulk Acoustic Wave and Surface Acoustic Wave devices.
2. It can be used to suppress undesired spurious modes in the response of MEMS or NEMS resonators
3. It can be used to improve the power handling of MEMS and NEMS resonators without causing a degradation in their electromechanical performance.

While example embodiments have been particularly shown and described, it will be understood by those skilled in the art that various changes in form and details may be made therein without departing from the scope of the embodiments encompassed or contemplated herein.

As used herein, “consisting essentially of” allows the inclusion of materials or steps that do not materially affect the basic and novel characteristics of the claim. Any recitation herein of the term “comprising”, particularly in a description of components of a composition or in a description of elements of a device, can be exchanged with “consisting essentially of” or “consisting of”.

What is claimed is:

1. An acoustic material contour-mode resonator (AM CMR) comprising:
an active region including:
a conductive plate suspended over a cavity in a substrate, wherein the conductive plate is anchored to the substrate outside the cavity by two anchor structures at opposite sides of the conductive plate orthogonal to a direction of vibration of the AM CMR (y-anchors),
a piezoelectric layer comprising a sheet disposed on the conductive plate, wherein the sheet comprises a piezoelectric material, and
an interdigitated metal structure (IDT) configured to generate an electric field in the piezoelectric layer to cause transduction for excitement of a longitudinal mode of vibration of the AM CMR; and
a pair of acoustic metamaterial reflectors (AMRs) forming lateral anchors anchored to the substrate and attached to opposite sides of the conductive plate along the direction of vibration of the AM CMR, the AMRs each including:
a conductive anchor plate suspended over the cavity in the substrate, and
a piezoelectric layer comprising a sheet disposed on the conductive plate, wherein the sheet comprises a piezoelectric material, and a parallel array of rods disposed on the sheet, wherein the sheet comprises a piezoelectric material;
wherein the AMRs are configured to generate an acoustic stopband for inhibiting lateral leakage of the excited longitudinal mode of vibration of the AM CMR.

2. The AM CMR of claim 1, wherein the IDT includes a plurality of electrodes configured to generate the electric field in the piezoelectric layer.

3. The AM CMR of claim 1, wherein the piezoelectric material is a highly doped aluminum nitride material.

4. The AM CMR of claim 3, wherein the piezoelectric material is Al_{0.72}Sc_{0.28}N.

5. The AM CMR of claim 1, wherein the parallel array of rods includes one or more rods.

6. The AM CMR of claim 5, wherein the parallel array of rods includes between one to 20 rods.

7. The AM CMR of claim 6, wherein the parallel array of rods includes seven rods.

8. The AM CMR of claim 1, wherein the rods comprise one or more of a dielectric, metallic, or piezoelectric material.

9. The AM CMR of claim 1, wherein a minimum length Lᵣ^{min} of each AMR lateral anchor for achieving [symbol] ₛ≥0.9 is less than a Lᵣ^{min} of a metal reflector (MR) attached to an MR CMR having a same active region as the AM CMR.

10. The AM CMR of claim 9, wherein a minimum length Lᵣ^{min} of each AMR lateral anchor for achieving [symbol] ₛ/ [symbol] ₘₐₓ≥0.9 is less than 100 μm.

11. The AM CMR of claim 10, wherein a minimum length Lᵣ^{min} of each AMR lateral anchor for achieving [symbol] ₛ≥0.9 is less than 70 μm.

12. The AM CMR of claim 1, wherein the piezoelectric layer comprises a corrugated structure, wherein the corrugated structure is characterized by a repeating unit-cell structure defined by a cross-section of the piezoelectric material sheet and the rods.

13. The AM CMR of claim 1, wherein each of the rods has a thickness (Tᵣ) of 350 nm.

14. The AM CMR of claim 1, wherein each of the rods has a width (Wᵣ) of 4 μm.

15. A method of fabricating an acoustic material contour-mode resonator (AM CMR) comprising the steps of:
depositing a conductive layer onto a substrate;
depositing a piezoelectric layer onto the conductive layer;
depositing an interdigitated metal structure (IDT) onto an active region portion of the piezoelectric layer;
forming, in two separate acoustic metamaterial reflector (AMR) portions of the piezoelectric layer, two corrugated structures each comprising an array of parallel rods; and
etching a release pit beneath the conductive layer, thereby forming the AM CMR.

16. The method of claim 15, wherein the step of forming the array of parallel rods in the piezoelectric layer of each of the two corrugated structures further comprises etching troughs into each of the two separate AMR portions of the piezoelectric layer.

17. The method of claim 15, wherein the step of forming the array of parallel rods in the piezoelectric layer of each of the two corrugated structures further comprises depositing a set of dielectric or conducting rods onto the piezoelectric layer in each of the two separate AMR portions of the piezoelectric layer.

18. The method of claim 15, wherein the AMR portions of the piezoelectric layer are positioned on opposite sides of and attached to the active region portion.

19. The method of claim 15, wherein, after the step of etching the release pit, the AMR portions of the piezoelectric layer remain anchored to the substrate.

20. The method of claim 15, wherein the method is CMOS compatible.
